(19) United States
(12) Patent Application Publication
(10) Pub. No.: US 2021/0293909 A1
(43) Pub. Date: Sep. 23, 2021

(54) MAGNETORESISTANCE EFFECT DEVICE AND SENSOR

(71) Applicant: TDK CORPORATION, Tokyo (JP)

(72) Inventors: Naomichi DEGAWA, Tokyo (JP); Tetsuya SHIBATA, Tokyo (JP)

(73) Assignee: TDK CORPORATION, Tokyo (JP)

(21) Appl. No.: 17/204,465

(22) Filed: Mar. 17, 2021

(30) Foreign Application Priority Data
Mar. 18, 2020 (JP) 2020-048246
Dec. 4, 2020 (JP) 2020-202177

(51) Int. Cl. G01R 33/09

(52) U.S. Cl. CPC G01R 33/093

(57) ABSTRACT

A magnetoresistance effect device includes: at least one magnetoresistance effect element; at least one first signal line; and an output port, wherein the magnetoresistance effect element includes a first ferromagnetic layer, a second ferromagnetic layer, and a spacer layer sandwiched between the first ferromagnetic layer and the second ferromagnetic layer, wherein the first signal line is separated from the magnetoresistance effect element with an insulator interposed therebetween and a high frequency magnetic field caused by a first high frequency current flowing through the first signal line is applied to the first ferromagnetic layer, wherein a high frequency current flows through the magnetoresistance effect element, and wherein a signal including a DC signal component caused by an output of the magnetoresistance effect element is output from the output port.

### BACKGROUND

The present disclosure relates to a magnetoresistance effect device and a sensor.

With the recent advanced information society, attention is focused on high-frequency components in the high-frequency band of GHz. Spintronics has been researched as a field that has the potential to be applied to new high-frequency components.

For example, Patent Document 1 describes a spin torque diode element using a spin torque diode effect. Patent Document 1 describes that the spin torque diode element is used as a rectifier. The spin torque diode effect is a rectification effect that uses a change in resistance of a magnetoresistance effect element.

### [Patent Documents]

[Patent Document 1] PCT International Publication No. WO2013/108357

### SUMMARY

In the spin torque diode element described in Patent document 1, a magnetization direction of a magnetic layer of the TMR element is changed by a spin transfer torque generated by an alternating current flowing through the TMR element and a DC voltage is output by multiplying the changing resistance of the TMR element with the alternating current. However, since the amplitude of the oscillation of magnetization using the spin transfer torque is small, it is difficult to output a large DC voltage.

It is desirable to provide a magnetoresistance effect device and a sensor having excellent output characteristics of DC signals.

A magnetoresistance effect device according to a first aspect includes: at least one magnetoresistance effect element; at least one first signal line; and an output port, wherein the magnetoresistance effect element includes a first ferromagnetic layer, a second ferromagnetic layer, and a spacer layer sandwiched between the first ferromagnetic layer and the second ferromagnetic layer, wherein the first signal line is separated from the magnetoresistance effect element with an insulator interposed therebetween and a high frequency magnetic field caused by a first high frequency current flowing through the first signal line is applied to the first ferromagnetic layer, wherein a high frequency current flows through the magnetoresistance effect element, and wherein a signal including a DC signal component caused by an output of the magnetoresistance effect element is output from the output port.

### BRIEF DESCRIPTION OF THE DRAWINGS

FIG. 1 is a diagram schematically showing a circuit configuration of a magnetoresistance effect device according to a first embodiment.

FIG. 2 is a schematic diagram illustrating an example of an operation as a magnetic sensor of the magnetoresistance effect device according to the first embodiment.

FIG. 3 is a diagram showing an example of a magnetization state of a first ferromagnetic layer and a second ferromagnetic layer of the magnetoresistance effect element in the magnetic sensor.

FIG. 4 is a diagram showing a relationship between a magnitude of an external magnetic field applied to the magnetoresistance effect element and a phase difference Δθ₂ between a phase of a first high frequency current and a phase of a resistance of the magnetoresistance effect element (a phase difference Δθ₁ between a phase of a second high frequency current and a phase of a resistance of the magnetoresistance effect element).

FIG. 5 is a diagram showing an example of a magnetization state of the first ferromagnetic layer and the second ferromagnetic layer of the magnetoresistance effect element in the magnetic sensor that detects a direction of an external magnetic field.

FIG. 6 is a diagram showing another example of the magnetization state of the first ferromagnetic layer and the second ferromagnetic layer of the magnetoresistance effect element in the magnetic sensor that detects the direction of the external magnetic field.

FIG. 7 is a diagram showing a time change of the resistance of the magnetoresistance effect element in a first pattern.

FIG. 8 is a diagram showing a time change of the resistance of the magnetoresistance effect element in a second pattern.

FIG. 9 is a plan view of a modified example of the magnetoresistance effect element shown in FIGS. 5(a) and 5(b).

FIG. 10 is a cross-sectional view of another modified example of the magnetoresistance effect element shown in FIGS. 5(a) and 5(b).

FIG. 11 is a diagram showing an example of the magnetization state of the first ferromagnetic layer and the second ferromagnetic layer of the magnetoresistance effect element in the magnetic sensor that detects a component of an external magnetic field in a lamination direction.

FIG. 12 is a diagram schematically showing an example of a circuit configuration in a case in which the magnetoresistance effect device according to the first embodiment is used as a rectifier.

FIG. 13 is a diagram showing an example of the magnetization state of the first ferromagnetic layer and the second ferromagnetic layer of the magnetoresistance effect element in the rectifier.

FIG. 14 is a diagram showing another example of the magnetization state of the first ferromagnetic layer and the second ferromagnetic layer of the magnetoresistance effect element in the rectifier.

FIG. 15 is a schematic diagram illustrating a first example when the magnetoresistance effect device is used as a dielectric sensor.

FIG. 16 is a schematic diagram illustrating a second example when the magnetoresistance effect device is used as the dielectric sensor.

FIG. 17 is a diagram illustrating a third example when the magnetoresistance effect device is used as the dielectric sensor.

FIG. 18 is a diagram schematically showing a circuit configuration of a magnetoresistance effect device according to a first modified example.

FIG. 19 is a perspective view showing the vicinity of a magnetoresistance effect element of a magnetoresistance effect device according to a second modified example.

FIG. 20 is a plan view showing the vicinity of the magnetoresistance effect element of the magnetoresistance effect device according to the second modified example.

FIG. 21 is another example of a plan view showing the vicinity of the magnetoresistance effect element of the magnetoresistance effect device according to the second modified example.

FIG. 22 is another example of a perspective view showing the vicinity of the magnetoresistance effect element of the magnetoresistance effect device according to the second modified example.

FIG. 23 is a diagram schematically showing a circuit configuration of a magnetoresistance effect device according to a third modified example.

FIG. 24 is a plan view showing the vicinity of a magnetoresistance effect element of the magnetoresistance effect device according to the third modified example.

FIG. 25 is a diagram showing a change in voltage corresponding to a DC voltage output from each magnetoresistance effect element and a change in addition average of a value corresponding to the DC voltage output from each magnetoresistance effect element in accordance with a change in the direction of the external magnetic field.

FIG. 26 is a diagram schematically showing a circuit configuration of a magnetoresistance effect device according to a fourth modified example.

FIG. 27 is a perspective view showing the vicinity of a first magnetoresistance effect element and a second magnetoresistance effect element of the magnetoresistance effect device according to the fourth modified example.

FIG. 28 is a diagram schematically showing another example of a circuit configuration of the magnetoresistance effect device according to the fourth modified example.

FIG. 29 is a diagram schematically showing another example of the circuit configuration of the magnetoresistance effect device according to the fourth modified example.

FIG. 30 is a perspective view showing the vicinity of a magnetoresistance effect element of a magnetoresi stance effect device according to a fifth modified example.

FIG. 31 is a diagram schematically showing a circuit configuration of a magnetoresistance effect device according to a second embodiment.

FIG. 32 is a diagram schematically showing a circuit configuration of a modified example of the magnetoresistance effect device according to the second embodiment.

FIG. 33 is a diagram schematically showing a circuit configuration of another modified example of the magnetoresistance effect device according to the second embodiment.

FIG. 34 is a diagram schematically showing a circuit configuration of another modified example of the magnetoresistance effect device according to the second embodiment.

FIG. 35 is a diagram schematically showing a circuit configuration of a magnetoresistance effect device according to a third embodiment.

FIG. 36 is a schematic diagram showing a case in which the magnetoresistance effect device according to the third embodiment is used as a dielectric sensor.

FIG. 37 is a schematic diagram showing a modified example of a case in which the magnetoresistance effect device according to the third embodiment is used as a dielectric sensor.

FIG. 38 is a schematic diagram showing another modified example of a case in which the magnetoresistance effect device according to the third embodiment is used as a dielectric sensor.

FIG. 39 is a diagram schematically showing a circuit configuration of a modified example of the magnetoresistance effect device according to the third embodiment.

FIG. 40 is a diagram schematically showing a circuit configuration of another modified example of the magnetoresistance effect device according to the third embodiment.

FIG. 41 is a diagram schematically showing a circuit configuration of another modified example of the magnetoresistance effect device according to the third embodiment.

### DETAILED DESCRIPTION

Hereinafter, a magnetoresistance effect device will be described as appropriate with reference to the drawings. In the drawings used in the following description, the featured parts may be enlarged for convenience of description for ease of understanding of the features and the dimensional ratios of respective components may differ from the actual ones. The materials, dimensions, and the like exemplified in the following description are examples, and the present disclosure is not limited thereto. The present disclosure can be appropriately modified within the range in which the effects of the present disclosure are exhibited.

### First Embodiment

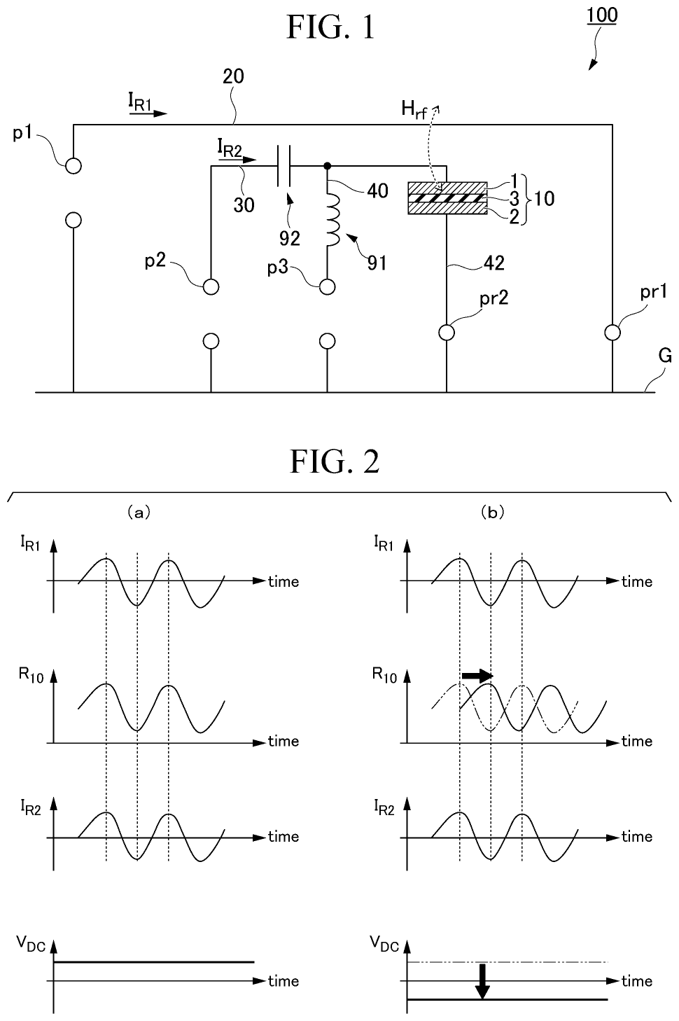

FIG. 1 is a diagram showing a circuit configuration of a magnetoresistance effect device 100 according to a first embodiment. The magnetoresistance effect device 100 includes a magnetoresistance effect element 10, a first input port p1, a first signal line 20, a second input port p2, a second signal line 30, and an output port p3. The magnetoresistance effect device 100 shown in FIG. 1 further includes lines 40 and 42, reference potential terminals pr1 and pr2, an inductor 91, and a capacitor 92.

<Magnetoresistance Effect Element>

The magnetoresistance effect element 10 includes a first ferromagnetic layer 1, a second ferromagnetic layer 2, and a spacer layer 3. The spacer layer 3 is located between the first ferromagnetic layer 1 and the second ferromagnetic layer 2. Hereinafter, the lamination direction of the first ferromagnetic layer 1, the second ferromagnetic layer 2, and the spacer layer 3 are simply referred to as the “lamination direction”.

The first ferromagnetic layer 1 is, for example, a magnetization free layer (a first magnetization free layer). The second ferromagnetic layer 2 is, for example, a magnetization fixed layer or a magnetization free layer (a second magnetization free layer). When the second ferromagnetic layer 2 functions as the magnetization fixed layer, the coercivity of the second ferromagnetic layer 2 is larger than, for example, the coercivity of the first ferromagnetic layer 1. The magnetization free layer is a layer which is formed of a magnetic material and in which a magnetization direction changes when a predetermined external force is applied and the magnetization fixed layer is a layer which is formed of a magnetic material and in which a magnetization direction is less likely to change than that of the magnetization free layer when a predetermined external force is applied. The predetermined external force is, for example, an external force applied to magnetization due to an external magnetic field.

In the magnetoresistance effect element 10, a resistance value in the lamination direction (a resistance value when a current flows in the lamination direction) changes in response to a change in the relative angle between the magnetization direction of the first ferromagnetic layer 1 and the magnetization direction of the second ferromagnetic layer 2. When the relative angle of the magnetization direction of the first ferromagnetic layer 1 with respect to the magnetization direction of the second ferromagnetic layer 2 changes, the second ferromagnetic layer 2 may be the magnetization fixed layer or the magnetization free layer.

The first ferromagnetic layer 1 and the second ferromagnetic layer 2 include a ferromagnetic material. For example, the first ferromagnetic layer 1 and the second ferromagnetic layer 2 can use metals such as Cr, Mn, Co, Fe, and Ni, or alloys containing one or more of these metal elements as constituent materials. Further, an alloy of the above metal elements and at least one or more elements selected from B, C and N may be used for the first ferromagnetic layer 1 and the second ferromagnetic layer 2. For example, the first ferromagnetic layer 1 and the second ferromagnetic layer 2 may have a CoFeB alloy as a main component when functioning as the magnetization free layer. Each of the first ferromagnetic layer 1 and the second ferromagnetic layer 2 may be composed of a plurality of layers.

Further, the first ferromagnetic layer 1 and the second ferromagnetic layer 2 may be an intermetallic compound (Heusler alloy) represented by a chemical composition of XYZ or X₂YZ. X is a transition metal element or a noble metal element from the Co, Fe, Ni, and Cu groups on the periodic table. Y is a transition metal from the Mn, V, Cr, and Ti groups or an element represented by X. Z is a typical element of Groups III to V. For example, Co₂FeSi, Co₂MnSi, Co₂Mn₁₋ₐFeₐAl_{b}Si_{1-b} (0≤a≤1, 0≤b=1), and the like are known as Heusler alloys.

The first ferromagnetic layer 1 and the second ferromagnetic layer 2 may be an in-plane magnetic film having an easy magnetization axis in the in-plane direction of the film surface or a perpendicular magnetization film having an easy magnetization axis in the direction perpendicular to the film surface.

In order to use the ferromagnetic layer as the in-plane magnetic film, the layer in contact with the ferromagnetic layer is made of a material that does not easily exhibit interfacial magnetic anisotropy. Examples of materials that do not easily exhibit interfacial magnetic anisotropy include Ru, Cu, and the like. On the other hand, in order to use the ferromagnetic layer as the perpendicular magnetization film, the layer in contact with the ferromagnetic layer is made of a material that easily exhibits interfacial magnetic anisotropy. Examples of materials that easily exhibit interfacial magnetic anisotropy include MgO, W, Ta, Mo, and the like. The layer of these materials in contact with the ferromagnetic layer may be provided on one side of the ferromagnetic layer in the direction perpendicular to the film surface. Further, the first ferromagnetic layer 1 or the second ferromagnetic layer 2 may be formed by a laminated film in which a layer of these materials in contact with the ferromagnetic layer is sandwiched between a plurality of ferromagnetic layers.

When the second ferromagnetic layer 2 functions as the magnetization fixed layer, an antiferromagnetic layer may be added to be in contact with the second ferromagnetic layer 2. Further, the magnetization of the second ferromagnetic layer 2 may be fixed by using the magnetic anisotropy caused by the crystal structure, shape, and the like. For the antiferromagnetic layer, FeO, CoO, NiO, CuFeS₂, IrMn, Femn, PtMn, Cr, Mn, or the like can be used.

The spacer layer 3 is a non-magnetic layer disposed between the first ferromagnetic layer 1 and the second ferromagnetic layer 2. The spacer layer 3 is formed as a layer composed of a conductor, an insulator, or a semiconductor or a layer including an energizing point formed of a conductor in the insulator.

For example, the magnetoresistance effect element 10 becomes a tunnel magnetoresistance (TMR) effect element when the spacer layer 3 is made of an insulator and becomes a giant magnetoresistance (GMR) effect element when the spacer layer 3 is made of metal.

When the spacer layer 3 is made of an insulating material, a material such as aluminum oxide, magnesium oxide, titanium oxide, or silicon oxide can be used. A high magnetoresistance change rate can be obtained by adjusting the film thickness of the spacer layer 3 so that a strong TMR effect is exhibited between the first ferromagnetic layer 1 and the second ferromagnetic layer 2. In order to efficiently use the TMR effect, the film thickness of the spacer layer 3 may be about 0.5 to 10.0 nm.

When the spacer layer 3 is made of a non-magnetic conductive material, a conductive material such as Cu, Ag, Au, or R₁₁ can be used. In order to efficiently use the GMR effect, the film thickness of the spacer layer 3 may be about 0.5 to 3.0 nm.

When the spacer layer 3 is made of a non-magnetic semiconductor material, a material such as zinc oxide, indium oxide, tin oxide, germanium oxide, gallium oxide, or ITO can be used. In this case, the film thickness of the spacer layer 3 may be about 1.0 to 4.0 nm.

When a layer including an energizing point composed of a conductor in a non-magnetic insulator is applied as the spacer layer 3, it may have a structure in which a non-magnetic insulator composed of aluminum oxide or magnesium oxide contains an energizing point composed of conductors such as CoFe, CoFeB, CoFeSi, CoMnGe, CoMnSi, CoMnAl, Fe, Co, Au, Cu, Al, or Mg. In this case, the film thickness of the spacer layer 3 may be about 0.5 to 2.0 nm.

Electrodes may be provided on both surfaces of the magnetoresistance effect element 10 in the lamination direction in order to increase the electrical conductivity of the magnetoresistance effect element 10. Since electrodes are provided on both end surfaces of the magnetoresistance effect element 10 in the lamination direction, the contact between each line and the magnetoresistance effect element 10 becomes a surface and a signal (current) flows along the lamination direction at any position in the in-plane direction of the magnetoresistance effect element 10.

The magnetoresistance effect element 10 may include other layers. For example, the magnetoresistance effect element 10 may have a seed layer or a buffer layer on the surface of the second ferromagnetic layer 2 opposite to the first ferromagnetic layer 1. Further, the magnetoresistance effect element 10 may have a cap layer on the surface of the first ferromagnetic layer 1 opposite to the second ferromagnetic layer 2. Examples of the cap layer, the seed layer, or the buffer layer include those of MgO, W, Mo, Ru, Ta, Cu, Cr, or a laminated film thereof. The film thickness of each of these layers may be about 2 to 10 nm.

<First Input Port>

The first input port p1 is a first input terminal of the magnetoresistance effect device 100. For example, an AC signal source, an antenna, or the like is connected to the first input port p1. If the antenna is integrated with the magnetoresistance effect device as a part of the magnetoresistance effect device, the antenna will be the first input port. The first input port p1 is connected to the first signal line 20. The first input port pl is connected to, for example, the end portion of the first signal line 20. A first high frequency signal is input to the first input port p1 and the first high frequency signal is input from the first input port p1 to the first signal line 20. The first high frequency signal produces a first high frequency current I_{R1} in the first signal line 20. The first high frequency signal is, for example, a signal having a frequency of 100 MHz or more. The first high frequency signal may be , for example, a signal having a frequency of 1 MHz or more. The frequency of the first high frequency current I_{R1} matches the frequency of the first high frequency signal.

<First Signal Line>

The first signal line 20 is a signal line through which the first high frequency current I_{R1} flows. The first signal line 20 shown in FIG. 1 is a line which connects the first input port p1 and the reference potential terminal pr1 to each other. The first signal line 20 shown in FIG. 1 electrically connects the first input port p1 and the reference potential terminal pr1 to each other.

The first signal line 20 is separated from the magnetoresistance effect element 10 and the second signal line 30 with an insulator interposed therebetween. The insulator may be an insulating material or a space. The first signal line 20 is disposed at a position in which a high frequency magnetic field H_{rf} produced by the first high frequency current I_{R1} flowing through the first signal line 20 can be applied to the first ferromagnetic layer 1. The high frequency magnetic field H_{rf} caused by the first high frequency current I_{R1} flowing through the first signal line 20 is applied to the first ferromagnetic layer 1. The magnetization of the first ferromagnetic layer 1 oscillates significantly when the frequency of the high frequency magnetic field H_{rf} applied to the first ferromagnetic layer 1 is close to the ferromagnetic resonance frequency of the first ferromagnetic layer 1. This phenomenon is a ferromagnetic resonance phenomenon. The frequency of the high frequency magnetic field H_{rf} matches the frequency of the first high frequency current IR₁. The first signal line 20 is closer to, for example, the first ferromagnetic layer 1 than to the second ferromagnetic layer 2.

<Second Input Port>

The second input port p2 is a second input terminal of the magnetoresistance effect device 100. For example, an AC signal source, an antenna, or the like is connected to the second input port p2. If the antenna is integrated with the magnetoresistance effect device as a part of the magnetoresistance effect device, the antenna will be the second input port. The second input port p2 is connected to the second signal line 30. The second input port p2 is connected to, for example, the end portion of the second signal line 30. A second high frequency signal is input to the second input port p2 and the second high frequency signal is input from the second input port p2 to the second signal line 30. The second high frequency signal produces a second high frequency current IR₂ in the second signal line 30. The second high frequency signal is, for example, a signal having a frequency of 100 MHz or more. The second high frequency signal may be, for example, a signal having a frequency of 1 MHz or more. The frequency of the second high frequency current IR₂ matches the frequency of the second high frequency signal.

<Second Signal Line>

The second signal line 30 is a signal line through which the second high frequency current IR₂ flows. The second signal line 30 shown in FIG. 1 is a line which connects the second input port p2 and the magnetoresistance effect element 10 to each other. The second signal line 30 shown in FIG. 1 electrically connects the second input port p2 and the magnetoresistance effect element 10 to each other.

The second signal line 30 is connected to the magnetoresistance effect element 10. The second high frequency current IR₂ flowing through the second signal line 30 flows through the magnetoresistance effect element 10. The amplitude of the oscillation of the magnetization of the first ferromagnetic layer 1 due to the high frequency magnetic field H_{rf} applied to the first ferromagnetic layer 1 is larger than the amplitude of the oscillation of the magnetization of the first ferromagnetic layer 1 due to the spin transfer torque generated by the second high frequency current IR₂ flowing through the magnetoresistance effect element 10.

<Output Port>

The output port p3 is an output terminal of the magnetoresistance effect device 100. For example, a voltmeter for monitoring a voltage or an ammeter for monitoring a current is connected to the output port p3. The output port p3 shown in FIG. 1 is connected to the line 40 branching from the second signal line 30. The output port p3 is connected to the magnetoresistance effect element and a signal including a DC signal component (DC voltage or DC current) caused by the output from the magnetoresistance effect element 10 is output from the output port p3.

<Other Configurations>

(Reference Potential Terminal)

The reference potential terminals pr1 and pr2 are connected to a reference potential and determine the reference potential of the magnetoresistance effect device 100. The reference potential terminal pr1 is connected to the first signal line 20. The reference potential terminal pr2 is connected to the line 42 connected to the magnetoresistance effect element 10. The reference potential of FIG. 1 is a ground G. The ground G may be provided outside the magnetoresistance effect device 100. The reference potential may be other than the ground G.

(Line)

The terminals are connected to each other by a line and the magnetoresistance effect element 10 and each terminal are connected to each other by a line. The shape of the line may be defined as a microstrip line (MSL) type or a coplanar wave guide (CPW) type. In the case of the design in the microstrip line (MSL) type or the coplanar wave guide (CPW) type, the line width and the distance between grounds may be designed so that the characteristic impedance of the line and the impedance of the circuit system are equal to each other. According to such a design, the transmission loss of the line can be suppressed.

The line 40 is a line branching from the second signal line 30. The line 40 connects the second signal line 30 and the output port p3 to each other. The line 42 connects the magnetoresistance effect element 10 and the reference potential terminal pr2 to each other.

(Inductor and Capacitor)

The inductor 91 cuts the high-frequency component of the signal and passes the invariant component of the signal. The capacitor 92 passes the high-frequency component of the signal and cuts the invariant component of the signal. The inductor 91 is disposed at a portion where the flow of the high frequency signal needs to be suppressed and the capacitor 92 is disposed at a portion where the flow of the DC signal needs to be suppressed.

The inductor 91 in FIG. 1 is located on the line 40. The inductor 91 suppresses the second high frequency current IR₂ and the high-frequency component of the output from the magnetoresistance effect element 10 from reaching the output port p3. As the inductor 91, a chip inductor, an inductor with a pattern line, a resistance element having an inductor component, or the like can be used. The inductance of the inductor 91 may be, for example, 10 nH or more. If the voltmeter or ammeter connected to the output port p3 has the function of cutting the high-frequency component of the signal and passing the invariant component of the signal, the inductor 91 may be omitted.

The capacitor 92 in FIG. 1 is located on the second signal line 30. The capacitor 92 in FIG. 1 is located between the second input port p2 and the branch point of the second signal line 30 with the line 40. A known one can be used for the capacitor 92.

<Magnetic Sensor>

The magnetoresistance effect device 100 can be used in, for example, a sensor, a rectifier, and the like. Examples of the sensor include a magnetic sensor (magnetic field sensor) that detects a magnetic field, a dielectric sensor that uses a dielectric as an object to be measured, and the like. First, a case in which the magnetoresistance effect device is used as the magnetic sensor will be described. Hereinafter, in the first embodiment, an example of a DC voltage will be described as a DC signal component output from the output port p3.

FIGS. 2(a) and 2(b) are schematic diagrams illustrating an operation as the magnetic sensor in the magnetoresistance effect device 100 according to the first embodiment. FIG. 2(a) shows a time change of the first high frequency current IR₁, the resistance R₁₀ of the magnetoresistance effect element 10, the second high frequency current 1R₂, and a DC voltage V_{DC} output from the output port p3 while a certain degree of an external magnetic field is applied to the magnetoresistance effect element 10. FIG. 2(b) shows a time change of the first high frequency current IR₁, the resistance R₁₀ of the magnetoresistance effect element 10, the second high frequency current IR₂, and the DC voltage V_{DC} output from the output port p3 after the external magnetic field applied to the magnetoresistance effect element 10 changes (increases). The external magnetic field is the magnetic field applied to the magnetoresistance effect element 10 from other than each configuration of the magnetoresistance effect device 100. Additionally, the arrow of the first high frequency current IR₁ and the arrow of the second high frequency current IR₂ shown in FIG. 1 respectively indicate the positive directions of currents. The same applies to the drawings to be described later.

First, a state before the external magnetic field applied to the magnetoresistance effect element 10 changes will be described. When the first high frequency signal is input to the first input port p1 from the AC signal source connected to the first input port pl, the first high frequency current IR₁ flows through the first signal line 20. The first high frequency current IR₁ causes the high frequency magnetic field H_{rf}. The high frequency magnetic field H_{rf} is applied to the first ferromagnetic layer 1 of the magnetoresistance effect element 10.

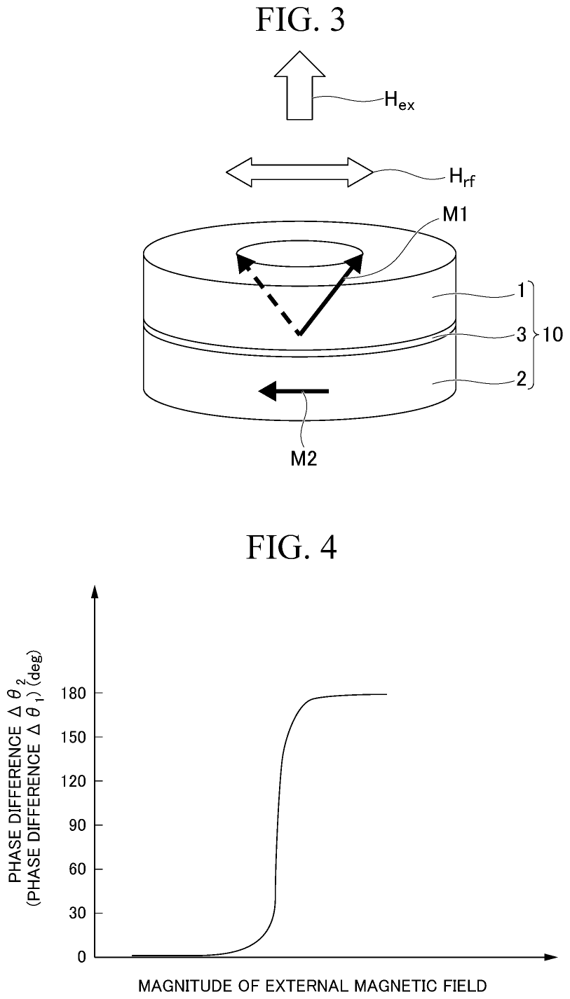

The magnetization of the first ferromagnetic layer 1 oscillates in response to the high frequency magnetic field H_{rf} caused by the first high frequency current IR₁. FIG. 3 is a diagram showing an example of the state of the magnetization M1 of the first ferromagnetic layer 1 and the magnetization M2 of the second ferromagnetic layer 2 in the magnetoresistance effect element 10 in the magnetic sensor. The magnetization M1 of the first ferromagnetic layer 1 oscillates (in a precession manner) due to the high frequency magnetic field H_{rf}. The second ferromagnetic layer 2 is the magnetization fixed layer and the direction of the magnetization M2 is fixed to be parallel to the oscillation direction of the high frequency magnetic field H_{rf}. An external magnetic field Hₑₓ is applied, for example, in the lamination direction.

In a state before the external magnetic field Hₑₓ applied to the magnetoresistance effect element 10 changes, as an example, the ferromagnetic resonance frequency of the first ferromagnetic layer 1 is smaller than the frequency of the high frequency magnetic field H_{rf} applied to the first ferromagnetic layer 1. The resistance R₁₀ of the magnetoresistance effect element 10 changes (oscillates) when the magnetization of the first ferromagnetic layer 1 oscillates. The phase of the first high frequency current IR₁ and the phase of the resistance R₁₀ of the magnetoresistance effect element 10 may be different from each other, but FIG. 2(a) shows an example in which these phases coincide with each other. The phase difference between the first high frequency current IR₁ and the resistance R₁₀ of the magnetoresistance effect element 10 can be changed by the arrangement position of the first signal line 20 with respect to the magnetoresistance effect element 10, the arrangement positions of the first input port p1 and the reference potential terminal pr1 with respect to the first signal line 20, and the relative angle between the direction of the high frequency magnetic field H_{rf} applied to the first ferromagnetic layer 1 and the magnetization direction of the second ferromagnetic layer.

When the second high frequency signal is input to the second input port p2 from the AC signal source connected to the second input port p2, the second high frequency current IR₂ flows through the second signal line 30. The second high frequency current IR₂ flows through the magnetoresistance effect element 10. The phase of the second high frequency current IR₂ and the phase of the first high frequency current IR₁ may be different from each other, but FIGS. 2(a) and 2(b) show an example in which these phases coincide with each other. That is, in the example shown in FIG. 2(a), the phase of the second high frequency current IR₂ coincides with the phase of the resistance R₁₀ of the magnetoresistance effect element 10.

When the first high frequency current IR₁ and the second high frequency current IR₂ are input to the magnetoresistance effect device 100, the DC voltage V_{DC} caused by the output from the magnetoresistance effect element 10 is output from the output port p3.

The DC voltage V_{DC} is a DC component of a voltage V (an output voltage from the magnetoresistance effect element 10) which is the product of the current (the second high frequency current IR₂) flowing through the magnetoresistance effect element 10 and the resistance R₁₀ of the magnetoresistance effect element 10 changing when the high frequency magnetic field H_{rf} caused by the first high frequency current IR₁ is applied thereto.

IR₂=A·sin(2πft)

R₁₀=B·sin(2πft+Δθ₁)+R₀

Then, the following formula is obtained.

V=IR₂×R₁₀=(A·B/2)·{cos(Δθ₁)−cos(4πft+Δθ₁)}+A·R₀·sin(2πft)

The DC voltage V_{DC} is the DC component of the voltage V and is (A·B/2) cos(Δθ₁).

Here, “A” indicates the amplitude of the second high frequency current IR₂, “B” indicates the amplitude of the resistance R₁₀ of the magnetoresistance effect element 10, R₀ indicates the resistance component not depending on the relative angle between the magnetization of the first ferromagnetic layer 1 and the magnetization of the second ferromagnetic layer 2 in the resistance of the magnetoresistance effect element 10, “f” indicates the frequency, “t” indicates the time, and Δθ₁ indicates the phase difference between the phase of the second high frequency current IR₂ and the phase of the resistance R₁₀ of the magnetoresistance effect element 10. Hereinafter, this will be simply referred to as the “phase difference Δθ₁”. Further, the phase difference between the phase of the first high frequency current IR₁ 0 and the phase of the resistance R₁₀ of the magnetoresistance effect element 10 will be simply referred to as Δθ₂ (hereinafter, simply referred to as the “phase difference Δθ₂”).

In the case shown in FIG. 2(a), Δθ₁=0)(0° and the DC voltage V_{DC} output from the output port p3 is A·B/2.

Next, a state after the external magnetic field Hₑₓ applied to the magnetoresistance effect element 10 changes (increases) will be described. When the external magnetic field Hₑₓ applied to the magnetoresistance effect element 10 changes, the oscillation (precession) state of the magnetization of the first ferromagnetic layer 1 changes. As a result, the phase of the resistance R₁₀ of the magnetoresistance effect element 10 changes. Since the phase of the second high frequency current IR₂ does not change, the phase difference Δθ₁ is generated between the phase of the second high frequency current IR₂ and the phase of the resistance R₁₀ of the magnetoresistance effect element 10. So far, an example in which the phase of the first high frequency current IR₁ coincides with the phase of the resistance R₁₀ of the magnetoresistance effect element 10 (Δθ₂=0(0°)) when the ferromagnetic resonance frequency of the first ferromagnetic layer 1 is sufficiently smaller than the frequency of the high frequency magnetic field H_{rf} (the frequency of the first high frequency current IR₁) has been described. In the case of this example, when the ferromagnetic resonance frequency of the first ferromagnetic layer 1 is sufficiently larger than the frequency of the high frequency magnetic field H_{rf}, the phase difference Δθ₂ is π(180°). When the external magnetic field Hₑₓ applied to the magnetoresistance effect element 10 increases so that the internal effective magnetic field in the first ferromagnetic layer 1 increases, the ferromagnetic resonance frequency of the first ferromagnetic layer 1 increases. Thus, in the case of this example, as shown in FIG. 4, the phase difference Δθ₂ or the phase difference Δθ₁ changes in response to a change in the magnitude of the external magnetic field applied to the magnetoresistance effect element 10.

As described above, the DC voltage V_{DC} is (A·B/2) cos(Δθ₁) and the output value of the DC voltage V_{DC} changes when the phase difference Δθ₁ changes. That is, the magnetoresistance effect device 100 can detect that the magnitude of the external magnetic field Hₑₓ changes based on the DC voltage V_{DC} output from the output port p3 and functions as the magnetic sensor. As an example, it is possible to detect a change from a state in which the phase difference Δθ₁ is 0(0°) to a state in which the phase difference Δθ₁ is π(180°). The value of the phase difference Δθ₁ before and after the change of the magnitude of the external magnetic field Hₑₓ is not limited to 0(0°) or π(180°) and can be an arbitrary value between 0 to π(0° to 180°). In the magnetoresistance effect device 100, since the magnetization of the first ferromagnetic layer 1 is oscillated by the high frequency magnetic field H_{rf} caused by the first high frequency current IR₁, the amplitude of the oscillation of the magnetization of the first ferromagnetic layer 1 can be increased. When the amplitude of the oscillation of the magnetization of the first ferromagnetic layer 1 increases, a change amount (amplitude) of the resistance R₁₀ of the magnetoresistance effect element 10 increases and hence a large DC voltage V_{DC} can be output from the output port p3.

Further, the magnetoresistance effect device 100 according to this embodiment can detect the magnitude or direction of the applied external magnetic field regardless of a change in the magnitude of the external magnetic field. Hereinafter, each detection method will be described.

(Detection of Magnitude of External Magnetic Field)

First, a method of detecting the magnitude of the external magnetic field will be described. For example, as shown in FIG. 3, if the magnitude of the external magnetic field Hₑₓ changes when the magnetization M2 of the second ferromagnetic layer 2 is oriented in the oscillation direction of the high frequency magnetic field H_{rf}, the phase difference Δθ₂ or the phase difference Δθ₁ changes as shown in FIG. 4. For example, the phase difference Δθ₂ or the phase difference Δθ₁ is 0(0°) (Δθ₁, Δθ₂=0) when the magnitude of the external magnetic field Hₑₓ is smaller than a first value and is π(180°) (Δθ₁, Δθ₂=π) when the magnitude of the external magnetic field Hₑₓ is larger than a second value (second value>first value). Then, when the magnitude of the external magnetic field Hₑₓ is equal to or larger than the first value and equal to or smaller than the second value, the magnitude of the external magnetic field Hₑₓ changes sharply. For that reason, the magnitude of the external magnetic field Hₑₓ and the phase differences Δθ₁ and Δθ₂ have a one-to-one relationship in an area in which the magnitude of the external magnetic field Hₑₓ is equal to or larger than the first value and equal to or smaller than the second value. That is, when the phase differences Δθ₁ and Δθ₂ are given, the magnitude of the external magnetic field Hₑₓ can be detected. As described above, the DC voltage V_{DC} is (A·B/2)·cos(Δθ₁). Thus, the phase difference Δθ₁ can be derived from the value of the DC voltage V_{DC} and the magnitude of the external magnetic field can be detected from the phase difference Δθ1. Further, a change amount of the magnitude of the external magnetic field can be obtained from a change amount of the value of the DC voltage V_{DC}. Further, the phase differences Δθ₁ and Δθ₂ change sharply with respect to a change in the external magnetic field Hₑₓ and the magnetic sensor can detect a difference in the magnitude of the external magnetic field Hₑₓ with high sensitivity.

(Detection of Direction of External Magnetic Field)

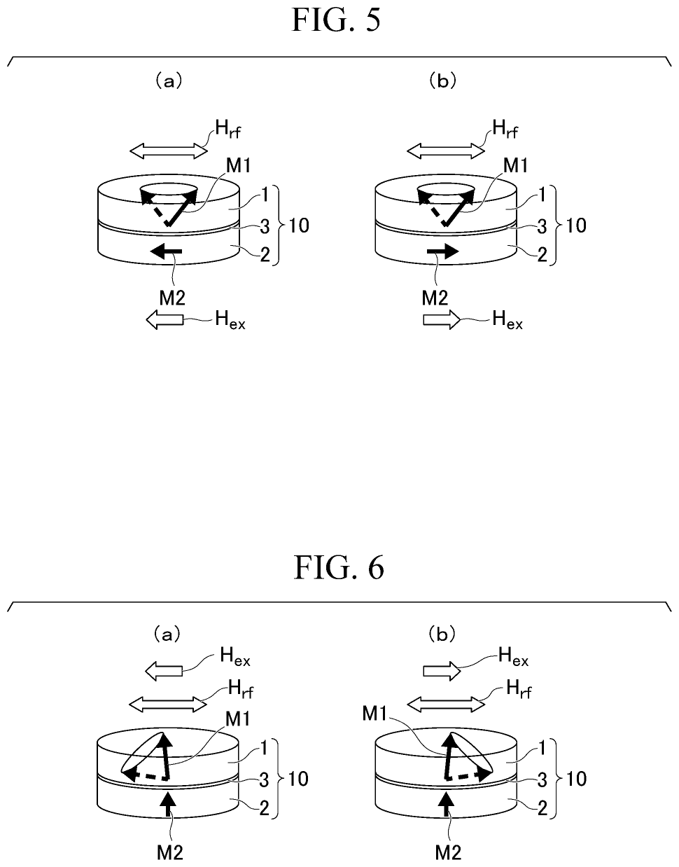

Next, a method of detecting the direction of the external magnetic field will be described. FIGS. 5(a) and 5(b) are diagrams showing an example of the state of the magnetization M1 of the first ferromagnetic layer 1 and the magnetization M2 of the second ferromagnetic layer 2 in the magnetoresistance effect element 10 when detecting the direction of the external magnetic field Hₑₓ. FIG. 5(a) shows a state in which the direction of the external magnetic field Hₑₓ is a first direction and FIG. 5(b) shows a state in which the direction of the external magnetic field Hₑₓ is different from the first direction.

Further, FIGS. 6(a) and 6(b) are diagrams showing another example of the state of the magnetization M1 of the first ferromagnetic layer 1 and the magnetization M2 of the second ferromagnetic layer 2 in the magnetoresistance effect element 10 when detecting the direction of the external magnetic field Hₑₓ. FIG. 6(a) shows a state in which the direction of the external magnetic field Hₑₓ is the first direction and FIG. 6(b) shows a state in which the direction of the external magnetic field Hₑₓ is different from the first direction.

A case of detecting the direction of the external magnetic field will be described with two patterns as a set of FIGS. 5(a) and 5(b) and a set of FIGS. 6(a) and 6(b).

First, a first pattern shown in FIGS. 5(a) and 5(b) will be described. In the first pattern, the magnetization M1 of the first ferromagnetic layer 1 oscillates (in a precession manner) due to the high frequency magnetic field H_{rf}, the external magnetic field Hₑₓ is applied to the second ferromagnetic layer 2, and the magnetization M2 of the second ferromagnetic layer 2 is oriented in the direction of the external magnetic field Hₑₓ. The second ferromagnetic layer 2 is the second magnetization free layer and the direction of the magnetization M2 of the second ferromagnetic layer 2 changes in response to the direction of the external magnetic field Hₑₓ. In an example of the first pattern, the first ferromagnetic layer 1 may have an easy magnetization axis in the direction perpendicular to the film surface in that the magnetization M1 is likely to oscillate (precession) due to the high frequency magnetic field H_{rf}. Further, in an example of the first pattern, the second ferromagnetic layer 2 may have an easy magnetization axis in the in-plane direction of the film surface in that the magnetization M2 is less likely to be influenced by the high frequency magnetic field H_{rf}.

For example, the magnetic sensor detects the direction of the external magnetic field Hₑₓ by the magnetoresistance effect element 10 of the first pattern. The first high frequency signal is input to the first input port p1 so that the first high frequency current IR₁ of the frequency f flows through the first signal line 20. The first high frequency current IR₁ generates the high frequency magnetic field H_{rf} of the frequency f. The high frequency magnetic field H_{rf} is applied to the first ferromagnetic layer 1 of the magnetoresistance effect element 10.

The second high frequency signal is input to the second input port p2 so that the second high frequency current IR₂ of the frequency f flows through the second signal line 30. The second high frequency current IR₂ flows through the magnetoresistance effect element 10. The phase of the second high frequency current IR₂ coincides with, for example, the phase of the first high frequency current IR₁. The phase of the second high frequency current IR₂ may be different from the phase of the first high frequency current IR₁.

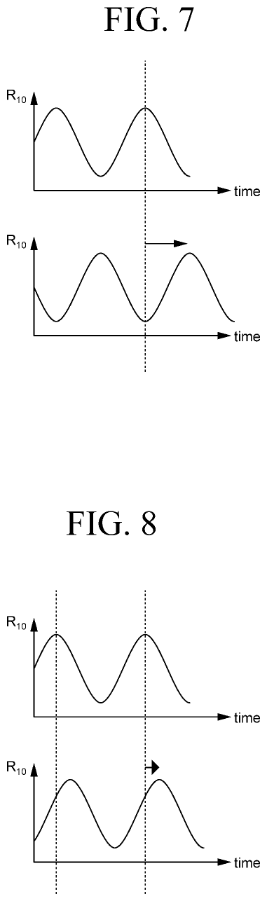

The resistance R₁₀ of the magnetoresistance effect element 10 changes in response to the change of the relative angle between the magnetization M1 of the first ferromagnetic layer 1 and the magnetization M2 of the second ferromagnetic layer 2. FIG. 7 is a diagram showing a time change of the resistance R₁₀ of the magnetoresistance effect element 10. The upper graph of FIG. 7 is a graph showing a time change of the resistance R₁₀ of the magnetoresistance effect element 10 while the external magnetic field Hₑₓ is applied in the first direction and the lower graph of FIG. 7 is a graph showing a time change of the resistance R₁₀ of the magnetoresistance effect element 10 while the external magnetic field Hₑₓ is applied in a direction different from the first direction.

When the direction of the external magnetic field Hₑₓ changes, the direction of the magnetization M2 of the second ferromagnetic layer 2 with respect to the center axis of the oscillation of the magnetization M1 of the first ferromagnetic layer 1 (the rotation axis of precession and hereinafter, simply referred to as the “rotation axis of the magnetization M1”) changes. As a result, the timing at which the resistance R₁₀ of the magnetoresistance effect element 10 becomes maximal or minimal changes and as shown in the lower graph of FIG. 7, the phase of the resistance R₁₀ of the magnetoresistance effect element 10 changes from the example shown in the upper graph of FIG. 7. When the phase of the resistance R₁₀ of the magnetoresistance effect element 10 changes, the phase difference Δθ₁ between the phase of the resistance R₁₀ and the phase of the second high frequency current IR₂ changes and the value of the DC voltage V_{DC} output from the output port p3 changes. That is, the magnetic sensor can detect the direction of the external magnetic field Hₑₓ applied to the magnetic sensor by reading the DC voltage V_{DC} output from the output port p3.

Next, the second pattern shown in FIGS. 6(a) and 6(b) will be described. In the second pattern, the magnetization M1 of the first ferromagnetic layer 1 oscillates (in a precession manner) due to the high frequency magnetic field H_{rf}. Further, in the second pattern, the second ferromagnetic layer 2 is the magnetization fixed layer and the direction of the magnetization M2 is fixed in the lamination direction. In the second pattern, the first ferromagnetic layer 1 and the second ferromagnetic layer 2 have an easy magnetization axis in the direction perpendicular to the film surface.

For example, the magnetic sensor detects the direction of the external magnetic field Hₑₓ by the magnetoresistance effect element 10 of the second pattern. The first high frequency signal is input to the first input port p1 so that the first high frequency current IR₁ of the frequency f flows through the first signal line 20. The first high frequency current IR₁ causes the high frequency magnetic field H_{rf} of the frequency f. The high frequency magnetic field H_{rf} is applied to the first ferromagnetic layer 1 of the magnetoresistance effect element 10.

The second high frequency signal is input to the second input port p2 so that the second high frequency current IR₂ of the frequency f flows through the second signal line 30. The second high frequency current IR₂ flows through the magnetoresistance effect element 10. For example, the phase of the second high frequency current IR₂ may coincide with the phase of the first high frequency current IR₁. The phase of the second high frequency current IR₂ may be different from the phase of the first high frequency current IR₁.

The resistance R₁₀ of the magnetoresistance effect element 10 changes in response to the change of the relative angle between the magnetization M1 of the first ferromagnetic layer 1 and the magnetization M2 of the second ferromagnetic layer 2. FIG. 8 is a diagram showing a time change of the resistance R₁₀ of the magnetoresistance effect element 10. The upper graph of FIG. 8 is a graph showing a time change of the resistance R₁₀ of the magnetoresistance effect element 10 while the external magnetic field Hₑₓ is applied in the first direction and the lower graph of FIG. 8 is a graph showing a time change of the resistance R₁₀ of the magnetoresistance effect element 10 while the external magnetic field Hₑₓ is applied in a direction different from the first direction.

The external magnetic field Hₑₓ is applied to the magnetoresistance effect element 10 and the external magnetic field Hₑₓ is applied to the first ferromagnetic layer 1 so that the rotation axis of the magnetization M1 of the first ferromagnetic layer 1 is inclined. The inclination direction of the rotation axis of the magnetization M1 changes in response to a change in the direction of the external magnetic field Hₑₓ. When the direction of the rotation axis of the magnetization M1 changes, the timing at which the resistance R₁₀ of the magnetoresistance effect element 10 becomes maximal or minimal changes. As a result, as shown in the lower graph of FIG. 8, the phase of the resistance R₁₀ of the magnetoresistance effect element 10 changes from the example shown in the upper graph of FIG. 8. When the phase of the resistance R₁₀ of the magnetoresistance effect element 10 changes, the phase difference 401 between the phase of the resistance R₁₀ and the phase of the second high frequency current IR₂ changes and the value of the DC voltage V_{DC} output from the output port p3 changes. That is, the magnetic sensor can detect the direction of the external magnetic field Hₑₓ applied to the magnetic sensor by reading the DC voltage V_{DC} output from the output port p3.

When the magnetic sensor shown in FIGS. 6(a) and 6(b) is used, the magnetic sensor can detect the magnitude of the component of the external magnetic field Hₑₓ in the in-plane direction (the direction perpendicular to the lamination direction of the magnetoresistance effect element 10). In FIGS. 6(a) and 6(b), the second ferromagnetic layer 2 is the magnetization fixed layer and the direction of the magnetization M2 is fixed to any of the lamination directions. The external magnetic field Hₑₓ is applied to the first ferromagnetic layer 1 in the in-plane direction. The rotation axis of the magnetization M1 of the first ferromagnetic layer 1 is inclined from the lamination direction by the external magnetic field Hₑₓ.

When the magnitude of the external magnetic field Hₑₓ changes, the inclination angle of the rotation axis of the magnetization M1 with respect to the lamination direction changes. For example, in the configuration shown in FIG. 6(a) or 6(b), when the magnitude of the external magnetic field Hₑₓ increases, the inclination angle of the rotation axis of the magnetization M1 with respect to the lamination direction also increases. Further, for example, in the configuration shown in FIG. 6(a) or 6(b), when the magnitude of the external magnetic field Hₑₓ decreases, the inclination angle of the rotation axis of the magnetization M1 with respect to the lamination direction decreases.

When the inclination angle of the rotation axis of the magnetization M1 with respect to the lamination direction changes, the magnitude of the amplitude of the resistance R₁₀ of the magnetoresistance effect element 10 changes. For example, in the case of the configuration shown in FIG. 6(a) or 6(b), when the inclination angle of the rotation axis of the magnetization M1 with respect to the lamination direction decreases, the orientation direction of the magnetization M1 and the orientation direction of the magnetization M2 are substantially parallel to each other and the magnitude of the amplitude of the resistance R₁₀ of the magnetoresistance effect element 10 decreases.

As described above, the resistance R₁₀ of the magnetoresistance effect element 10 is a parameter that influences the DC voltage V_{DC} output from the output port p3. As a result, when the magnitude of the external magnetic field Hₑₓ applied to the magnetoresistance effect element 10 changes, the value of the DC voltage V_{DC} output from the output port p3 changes. That is, the magnetic sensor can detect the magnitude of the external magnetic field Hₑₓ in the in-plane direction applied to the magnetic sensor by reading the DC voltage V_{DC} output from the output port p3.

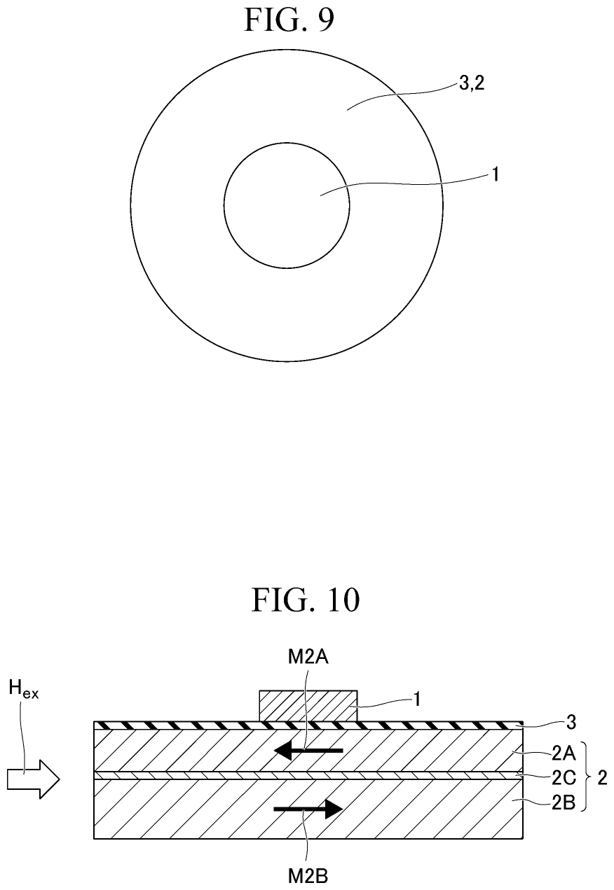

Further, FIG. 9 is a plan view of a modified example of the magnetoresistance effect element 10 shown in FIGS. 5(a) and 5(b). The first ferromagnetic layer 1 shown in FIG. 9 is smaller than the second ferromagnetic layer 2 in the plan view in the film thickness direction. The first ferromagnetic layer 1 shown in FIG. 9 is included in the second ferromagnetic layer 2 in the plan view in the film thickness direction. Accordingly, the influence of the oscillation of the magnetization of the first ferromagnetic layer 1 is less likely to reach the entirety of the second ferromagnetic layer 2.

Further, FIG. 10 is a cross-sectional view of another modified example of the magnetoresistance effect element 10 shown in FIGS. 5(a) and 5(b). The second ferromagnetic layer 2 shown in FIG. 10 includes two ferromagnetic layers 2A and 2B and a non-magnetic layer 2C sandwiched therebetween. The non-magnetic layer 2C is, for example, Ru. The ferromagnetic layer 2A and the ferromagnetic layer 2B are interconnected with each other via the non-magnetic layer 2C. The magnetization M2A of the ferromagnetic layer 2A and the magnetization M2B of the ferromagnetic layer 2B are antiparallel.

The product of the film thickness and the saturation magnetization of the ferromagnetic layer 2A is different from the product of the film thickness and the saturation magnetization of the ferromagnetic layer 2B. When the product of the film thickness and the saturation magnetization is different for two ferromagnetic layers 2A and 2B, the magnetization of the ferromagnetic layer having a larger product of the film thickness and the saturation magnetization is more likely to react to the magnetic field applied from the outside than the magnetization of the ferromagnetic layer having a smaller product of the film thickness and the saturation magnetization, so that the magnetization direction of the second ferromagnetic layer 2 is likely to change due to the external magnetic field Hₑₓ.

For example, the film thickness of the ferromagnetic layer 2A is different from the film thickness of the ferromagnetic layer 2B. When the film thicknesses of two ferromagnetic layers 2A and 2B are different, the product of the film thickness and the saturation magnetization is different in two ferromagnetic layers 2A and 2B in many cases. For example, the film thickness of the ferromagnetic layer 2B is thicker than the film thickness of the ferromagnetic layer 2A. For example, the film thickness of the ferromagnetic layer 2B is twice or more the film thickness of the ferromagnetic layer 2A. The product of the film thickness and the saturation magnetization of the ferromagnetic layer 2B is larger than the product of the film thickness and the saturation magnetization of the ferromagnetic layer 2A. The ferromagnetic layer 2B is located at a position further away from the first ferromagnetic layer 1 and the first signal line 20 than the ferromagnetic layer 2A. When the film thickness of the ferromagnetic layer 2B is thicker than the film thickness of the ferromagnetic layer 2A and the ferromagnetic layer which easily reacts to the magnetic field applied from the outside in the ferromagnetic layers included in the second ferromagnetic layer 2 is the ferromagnetic layer 2B, it is possible to reduce the influence of the oscillation of the magnetization of the first ferromagnetic layer 1 or the influence of the high frequency magnetic field from the first signal line 20 and it is possible to suppress the oscillation of the magnetization of the second ferromagnetic layer 2 when the second ferromagnetic layer 2 is viewed as a whole.

In FIG. 10, an example in which the first ferromagnetic layer 1 is smaller than the second ferromagnetic layer 2 in the plan view in the film thickness direction is presented, but the present disclosure is not limited thereto. Further, each of the ferromagnetic layer 2A and the ferromagnetic layer 2B may include a plurality of layers.

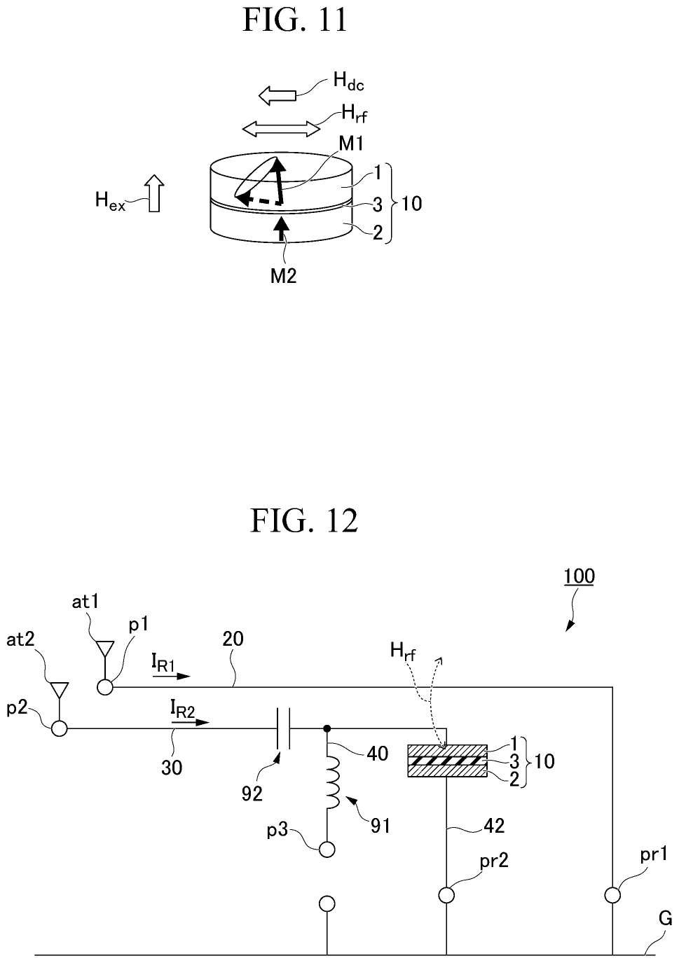

So far, some methods in which the magnetic sensor detects the component of the external magnetic field Hₑₓ in the in-plane direction (the direction perpendicular to the lamination direction of the magnetoresistance effect element 10) have been described, but the magnetic sensor can also detect the component of the external magnetic field Hₑₓ in the lamination direction. FIG. 11 is a diagram showing an example of the magnetization state of the first ferromagnetic layer 1 and the second ferromagnetic layer 2 of the magnetoresistance effect element 10 in the magnetic sensor that detects the component of the external magnetic field Hₑₓ in the lamination direction.

The second ferromagnetic layer 2 is the magnetization fixed layer and the direction of the magnetization M2 is fixed to any of the lamination directions. A static magnetic field H_{dc} is applied to the first ferromagnetic layer 1. The rotation axis of the magnetization M1 of the first ferromagnetic layer 1 is inclined from the lamination direction by the static magnetic field H_{dc}. The static magnetic field H_{dc} is applied in a direction parallel or antiparallel to the oscillation direction of the high frequency magnetic field H_{rf}. To apply the static magnetic field H_{dc} in a direction parallel or antiparallel to the oscillation direction of the high frequency magnetic field H_{rf} means that the component of the static magnetic field H_{dc} in the in-plane direction is present in a direction in which the high frequency magnetic field H_{rf} oscillates in the first ferromagnetic layer 1. When the first direction is defined in the oscillation direction of the high frequency magnetic field H_{rf}, a case in which the static magnetic field H_{dc} is applied in the same direction as the first direction is a parallel state and a case in which the static magnetic field H_{dc} is applied in a direction opposite to the first direction is an antiparallel state.

When the magnitude of the external magnetic field Hₑₓ or the positive or negative direction thereof changes, the inclination angle of the rotation axis of the magnetization M1 with respect to the lamination direction changes. For example, in the configuration shown in FIG. 11, when the magnitude of the external magnetic field Hₑₓ increases, the inclination angle of the rotation axis of the magnetization M1 with respect to the lamination direction decreases. Further, for example, in the configuration shown in FIG. 11, when the magnitude of the external magnetic field Hₑₓ decreases or the direction of the external magnetic field Hₑₓ becomes opposite, the inclination angle of the rotation axis of the magnetization M1 with respect to the lamination direction increases.

When the inclination angle of the rotation axis of the magnetization M1 with respect to the lamination direction changes, the magnitude of the amplitude of the resistance R₁₀ of the magnetoresistance effect element 10 changes. For example, in the case of the configuration shown in FIG. 11, when the inclination angle of the rotation axis of the magnetization M1 with respect to the lamination direction decreases, the orientation direction of the magnetization M1 and the orientation direction of the magnetization M2 become substantially parallel to each other and the magnitude of the amplitude of the resistance R₁₀ of the magnetoresistance effect element 10 decreases.

As described above, the resistance R₁₀ of the magnetoresistance effect element 10 is a parameter that influences the DC voltage V_{DC} output from the output port p3. As a result, when the magnitude of the external magnetic field Hₑₓ applied to the magnetoresistance effect element 10 changes, the value of the DC voltage V_{DC} output from the output port p3 changes. That is, the magnetic sensor can detect the magnitude of the external magnetic field Hₑₓ applied to the magnetic sensor and the positive or negative direction thereof by reading the DC voltage V_{DC} output from the output port p3.

Here, in FIG. 11, a case in which the static magnetic field H_{dc} is applied to the first ferromagnetic layer 1 has been described as an example. However, the static magnetic field H_{dc} may not be essentially applied to the first ferromagnetic layer 1 and an in-plane component of an effective magnetic field H_{eff} in the first ferromagnetic layer 1 may be parallel or antiparallel to the oscillation direction of the high frequency magnetic field H_{rf} applied to the first ferromagnetic layer 1. The effective magnetic field H_{eff} in the first ferromagnetic layer 1 is obtained as H_{eff}=Hₑₓ+Hₖ+H_{D}+H_{Eg} from the external magnetic field Hₑₓ applied to the first ferromagnetic layer 1, an anisotropic magnetic field Hₖ in the first ferromagnetic layer 1, an anti-magnetic field H_{D} in the first ferromagnetic layer 1, and an exchange coupling magnetic field H_{Eg} in the first ferromagnetic layer 1. For example, when the shape of the first ferromagnetic layer 1 when viewed from the lamination direction has anisotropy, the anisotropic magnetic field Hₖ is generated in the longitudinal direction thereof. The anisotropic magnetic field Hₖ may be generated in the first ferromagnetic layer 1 instead of the static magnetic field H_{dc} by directing the longitudinal direction of the first ferromagnetic layer 1 when viewed from the lamination direction to the oscillation direction of the high frequency magnetic field H_{rf} applied to the first ferromagnetic layer 1.

So far, an example has been shown in which the DC component of the voltage V (the output voltage from the magnetoresistance effect element 10) is used to detect the change of the magnitude of the external magnetic field, the magnitude of the external magnetic field, and the direction of the external magnetic field, but the high-frequency component of the voltage may be used. Since −(A·B/2)·cos(4πft+Δθ₁) which is the high-frequency component of the voltage V includes the phase difference Δθ₁, the phase difference Δθ₁ can be derived from the high-frequency component. When the phase difference Δθ₁ is given, the external magnetic field can be detected from the phase difference Δθ₁.

<Rectifier>

So far, a case in which the magnetoresistance effect device 100 is used as the magnetic sensor has been described. Next, a case in which the magnetoresistance effect device 100 is used as a rectifier will be described.

FIG. 12 is a diagram schematically showing an example of a circuit configuration when the magnetoresistance effect device 100 is used as the rectifier. As an example of using the magnetoresistance effect device 100 as the rectifier, an example in which an antenna at1 is connected to the first input port p1 and an antenna at2 is connected to the second input port p2 will be described. For example, the same signal is input to the antennas at1 and at2.

When the first high frequency signal is input from the antenna at1 to the first input port p1, the first high frequency current IR₁ flows through the first signal line 20. Further, when the second high frequency signal is input from the antenna at2 to the second input port p2, the second high frequency current IR₂ flows through the second signal line 30. The first high frequency current IR₁ causes the high frequency magnetic field H. The high frequency magnetic field H_{rf} is applied to the first ferromagnetic layer 1 of the magnetoresistance effect element 10. The second high frequency current IR₂ flows through the magnetoresistance effect element 10. The phase of the second high frequency current IR₂ and the phase of the first high frequency current IR₁ may be different from each other, but here, an example in which these phases coincide with each other will be described.

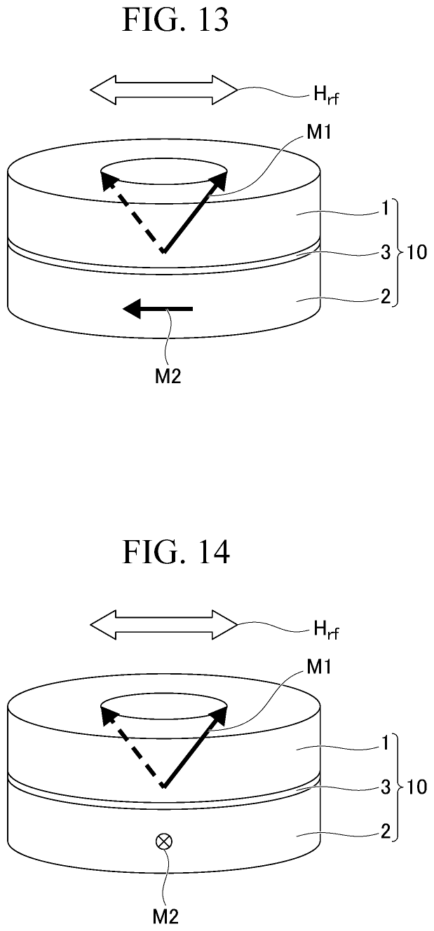

FIG. 13 is a diagram showing an example of the state of the magnetization M1 of the first ferromagnetic layer 1 and the magnetization M2 of the second ferromagnetic layer 2 in the magnetoresistance effect element 10. FIG. 14 is a diagram showing another example of the state of the magnetization M1 of the first ferromagnetic layer 1 and M2 of the second ferromagnetic layer 2 in the magnetoresistance effect element 10. In the examples of FIGS. 13 and 14, the second ferromagnetic layer 2 functions as the magnetization fixed layer.

When the frequency of the high frequency magnetic field H_{rf} is a frequency different from the ferromagnetic resonance frequency of the first ferromagnetic layer 1 (when the frequency is not in the vicinity of the ferromagnetic resonance frequency of the first ferromagnetic layer 1), as an example, the direction of the magnetization M2 is parallel to the oscillation direction of the high frequency magnetic field H_{rf} as shown in FIG. 13. When the frequency of the high frequency magnetic field H_{rf} is the ferromagnetic resonance frequency of the first ferromagnetic layer, as an example, the direction of the magnetization M2 may be orthogonal to the oscillation direction of the high frequency magnetic field H_{rf} as shown in FIG. 14.

The magnitude of the DC voltage V_{DC} output from the output port p3 is proportional to cos(Δθ₁). In order to increase the magnitude (absolute value) of the DC voltage V_{DC}, Δθ₁ may be 0(0°) or ±π(±180°). Since the phase of the first high frequency current IR₁ coincides with the phase of the second high frequency current IR₂, the phase difference Δθ₂ coincides with the phase difference Δθ₁.

When the frequency of the high frequency magnetic field H_{rf} is not in the vicinity of the ferromagnetic resonance frequency of the first ferromagnetic layer 1, the phase difference Δθ₁ becomes 0(0°) or ±π(±180°) by the configuration of FIG. 13 and hence the magnitude of the DC voltage V_{DC} output from the output port p3 increases.

In contrast, when the frequency of the high frequency magnetic field H_{rf} is the ferromagnetic resonance frequency of the first ferromagnetic layer 1, the phase difference Δθ₁ becomes 0 (0°) or ±π(±180°) by the configuration of FIG. 14 and hence the magnitude of the DC voltage V_{DC} output from the output port p3 increases.

Further, in FIG. 14, an example has been shown in which the direction of the magnetization M2 of the second ferromagnetic layer 2 is orthogonal to the oscillation direction of the high frequency magnetic field H_{rf} in advance, but when the high frequency magnetic field H_{rf} applied to the first ferromagnetic layer 1 is the ferromagnetic resonance frequency of the first ferromagnetic layer 1, the direction of the magnetization M2 of the second ferromagnetic layer 2 may be parallel to the oscillation direction of the high frequency magnetic field H_{rf} and the phase of the second high frequency current IR₂ may shift by π/2(90°) with respect to the phase of the first high frequency current IR₁ similarly to the configuration of FIG. 13. For example, when a phase shifter is provided on at least one of the first signal line 20 and the second signal line 30, at least one of the phase of the first high frequency current IR₁ and the phase of the second high frequency current IR₂ can be adjusted.

<Dielectric Sensor>

Next, a case in which the magnetoresistance effect device 100 is used as a dielectric sensor using a dielectric as an object to be measured will be described. The dielectric sensor is, for example, a sensor that determines the state of the object to be measured based on a difference in permittivity of the object to be measured. The dielectric sensor is a sensor that uses the characteristic that the phase and amplitude of a signal propagating in a signal line changes by bringing the dielectric close to the signal line or installing the dielectric in the signal propagation path. The dielectric sensor can measure the amount of water of these measured objects, for example, when vegetables, grains, skin, and the like are used as the objects to be measured.

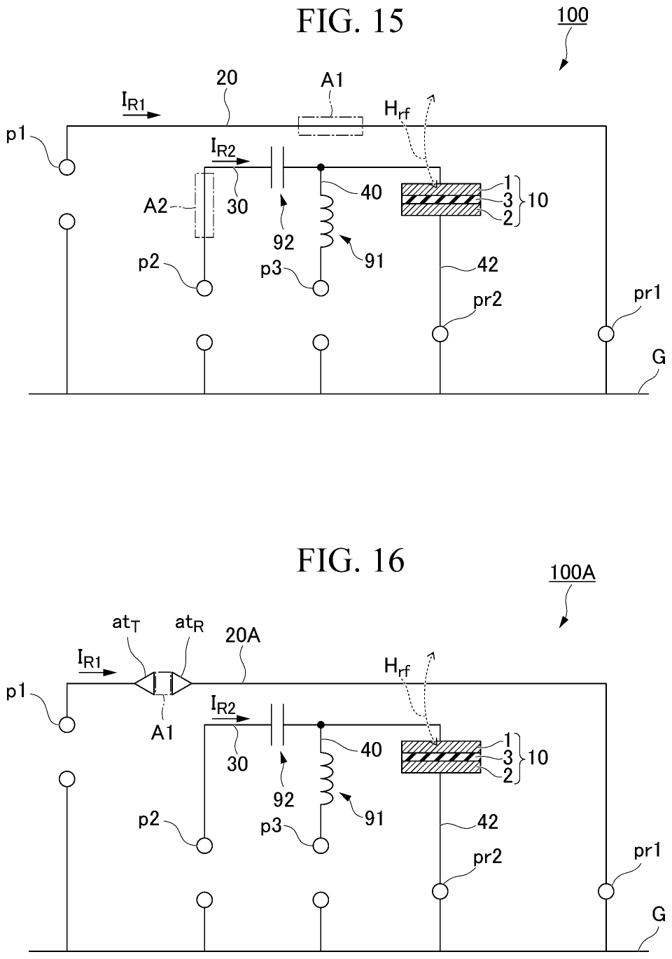

FIG. 15 is a schematic diagram illustrating a first example of a case in which the magnetoresistance effect device 100 is used as a dielectric sensor. The dielectric sensor shown in the first example includes an installation area A1 or an installation area A2. For example, a part of the first signal line 20 which is formed in a microstrip line type or a coplanar wave guide type is disposed in the installation area A1. For example, a part of the second signal line 30 which is formed in a microstrip line type or a coplanar wave guide type is disposed in the installation area A2. A dielectric object to be measured is installed in either the installation area A1 or the installation area A2 and measurement is performed. The object to be measured is not particularly limited.

As the magnetoresistance effect element 10 when the magnetoresistance effect device 100 is used as the dielectric sensor, for example, one shown in FIG. 13 can be used.

First, an operation of the sensor when the object to be measured is installed in the installation area A1 will be described. The first high frequency current IR₁ and the second high frequency current IR₂ in the state before the installation of the object to be measured are set as below.

IR₂=A·sin(2πft)

IR₁=C·sin(2πft+Δθ₃)

Here, Δθ₃ is the phase difference between IR₁ and IR₂ and is constant.

When the phase difference between IR₁ and the resistance R₁₀ of the magnetoresistance effect element 10 is Δθ₂, the resistance R₁₀ of the magnetoresistance effect element 10 is expressed by the following formula.

R₁₀=B·sin(2πft+Δθ₂+Δθ₃)+R₀

Here, since the measurement is performed in a condition that the external magnetic field is constant, Δθ₂ is constant.

When the object to be measured is installed in the installation area A1, the phase of IR₁ shifts by Δθ₄ and the amplitude of IR₁ changes to C′ in accordance with the change of the permittivity (the change from the permittivity of air to the permittivity of the object to be measured).

As a result, the first high frequency current 1R1 and the resistance R₁₀ of the magnetoresistance effect element 10 are as below.

IR₁=C′·sin(2πft+Δθ₃+Δθ₄)

R₁₀=B′·sin(2πft+Δθ₂+Δθ₃+Δθ₄)+R₀

Here, when the phase difference between IR₁ and R₁₀ is Δθ₁(=Δθ₂+Δθ₃+Δθ₄), R₁₀=B′·sin(2πft+Δθ₁)+R₀ is obtained.

As described above, the DC voltage V_{DC} output from the output port p3 is the DC component of the voltage V (the output voltage from the magnetoresistance effect element 10) which is the product of the resistance R₁₀ of the magnetoresistance effect element 10 and the current (the second high frequency current IR₂) flowing through the magnetoresistance effect element 10 and is expressed by the following formula.

V=IR₂×R₁₀=(A·B′/2)·{cos(Δθ₁)−cos(4πft+Δθ₁)}+A·R₀·sin(2πft)

The DC voltage V_{DC} is the DC component of the voltage V and is (A·B′/2)cos(Δθ₁). Since Δθ₁=Δθ₂+Δθ₃+Δθ₄ and Δθ₂ and Δθ₃ are constant, the DC output component corresponding to the values of Δθ₄ and B′ which change in accordance with the change of the permittivity is output from the output port p3. Based on this result, parameters related to the permittivity of the object to be measured (for example, the amount of water in the object to be measured) can be measured.

Next, an operation of the sensor when the object to be measured in installed in the installation area A2 will be described. A state before the installation of the object to be measured is the same as the case in which the object to be measured is installed in the installation area A1.

When the object to be measured is installed in the installation area A2, the phase of IR₂ shifts by Δθ₄ and the amplitude of IR₂ changes to A′ in accordance with the change of the permittivity (the change from the permittivity of air to the permittivity of the object to be measured).

As a result, the second high frequency current IR₂ and the resistance R₁₀ of the magnetoresistance effect element 10 are as below.

IR₂=A′·sin(2πft+Δθ₄)

R₁₀=B·sin(2πft+Δθ₂+Δθ₃)+R₀

Here, the above formulas can be rephrased as below based on the phase of IR₂ after the installation of the object to be measured in the installation area A2 due to mathematical handling.

IR₂=A′·sin(2πft)

R₁₀=B·sin(2πft+Δθ₂+Δθ₃−Δθ₄)+R₀

IR₁=C·sin(2πft+Δθ₃−Δθ₄)

Here, when the phase difference between IR₁ and R₁₀ is Δθ₁(=Δθ₂+Δθ₃−Δθ₄), R₁₀=B·sin(2πft+Δθ₁)+R₀ is obtained.

As described above, the DC voltage V_{DC} output from the output port p3 is the DC component of the voltage V (the output voltage from the magnetoresistance effect element 10) which is the product of the resistance R₁₀ of the magnetoresistance effect element 10 and the current (the second high frequency current IR₂) flowing through the magnetoresistance effect element 10 and the same relational expression as when the object to be measured is installed in the installation area A1 is established.

The DC voltage V_{DC} is the DC component of the voltage V and is (A′·B/2)·cos(Δθ₁). Since Δθ₁=Δθ₂+Δθ₃−Δθ₄ and Δθ₂ and Δθ₃ are constant, the DC output component corresponding to the values of Δθ₄ and A′ which change in accordance with the change of the permittivity is output from the output port p3. Based on this result, parameters related to the permittivity of the object to be measured (for example, the amount of water in the object to be measured) can be measured.

Further, FIG. 16 is a schematic diagram illustrating a second example when the magnetoresistance effect device is used as a dielectric sensor. In a magnetoresistance effect device 100A shown in the second example, a first signal line 20A includes a transmission antenna at_{T} and a reception antenna at_{R} and the installation area A1 is an area sandwiched between the transmission antenna at_{T} and the reception antenna at_{R}. The transmission antenna at_{T} transmits the first high frequency signal, transmitted to the first signal line, to the reception antenna at_{R}. When the object to be measured is installed in the installation area A1, the phase and the amplitude of IR₁ change in accordance with the change of the permittivity (the change from the permittivity of air to the permittivity of the object to be measured). As a result, the magnitude of the DC voltage V_{DC} output from the output port p3 changes. This principle is the same as the case where the object to be measured is installed in the installation area A1 in the first example. Based on this result, parameters related to the permittivity of the object to be measured (for example, the amount of water in the object to be measured) can be measured.

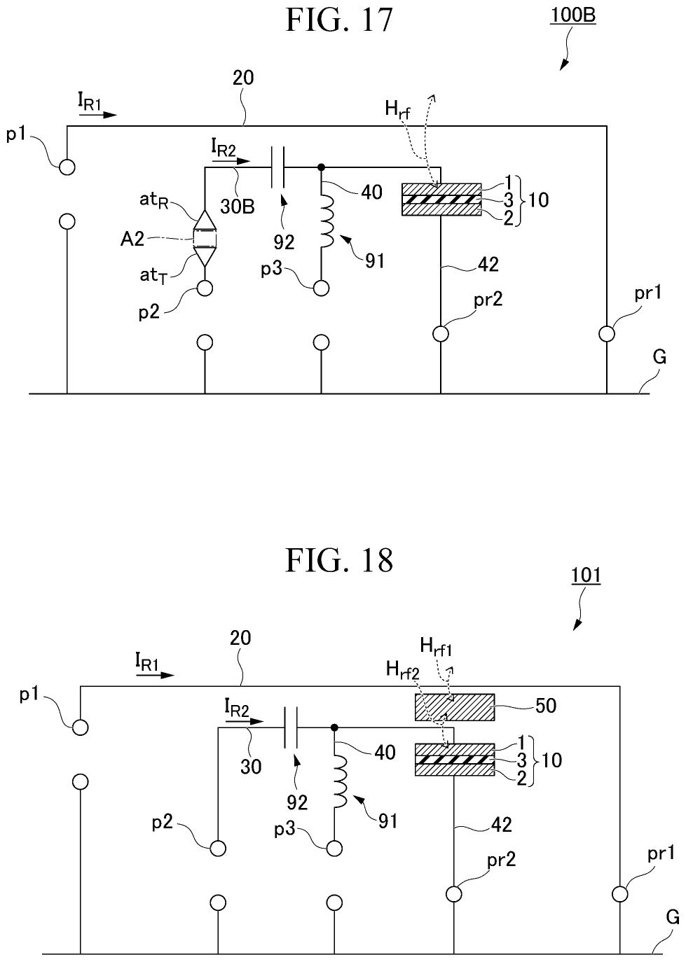

Further, FIG. 17 is a schematic diagram illustrating a third example when the magnetoresistance effect device is used as a dielectric sensor. In a magnetoresistance effect device 100B shown in the third example, a second signal line 30B includes a transmission antenna at_{T} and a reception antenna at_{R} and the installation area A2 is an area sandwiched between the transmission antenna at_{T} and the reception antenna at_{R}. The transmission antenna at_{T} transmits the second high frequency signal, transmitted to the second signal line, to the reception antenna at_{R}. When the object to be measured is installed in the installation area A2, the phase and the amplitude of IR₂ change in accordance with the change of the permittivity (the change from the permittivity of air to the permittivity of the object to be measured). As a result, the magnitude of the DC voltage V_{DC} output from the output port p3 changes. This principle is the same as the case where the object to be measured is installed in the installation area A2 in the first example. Based on this result, parameters related to the permittivity of the object to be measured (for example, the amount of water in the object to be measured) can be measured.

As described above, since the magnetoresistance effect device 100 according to the first embodiment oscillates the magnetization M1 of the first ferromagnetic layer 1 by the high frequency magnetic field H_{rf} caused by the first high frequency current IR₁, the amplitude of the oscillation of the magnetization M1 can be increased. When the amplitude of the oscillation of the magnetization M1 increases, the change amount (amplitude) of the resistance R₁₀ of the magnetoresistance effect element 10 increases and hence a large DC voltage V_{DC} can be output from the output port p3. Further, as described above, the magnetoresistance effect device 100 according to the first embodiment can be used as the magnetic sensor, the rectifier, and the dielectric sensor that uses the dielectric as the object to be measured.

Although the first embodiment has been described with reference to the drawings, each configuration in the first embodiment and a combination thereof are examples and the configuration can be added, omitted, replaced, and modified in other forms without departing from the spirit of the present disclosure. For example, in the first embodiment, the magnetoresistance effect element 10 is one example. However, a plurality of magnetoresistance effect elements 10 may be connected to the second signal line 30 so that the second high frequency current IR₂ flows through the plurality of magnetoresistance effect elements 10 and the high frequency magnetic field H_{rf} caused by the first high frequency current IR₁ flowing through the first signal line 20 may be applied to the first ferromagnetic layers 1 of the plurality of magnetoresistance effect elements 10.

### FIRST MODIFIED EXAMPLE

FIG. 18 is a diagram schematically showing a circuit configuration of a magnetoresistance effect device according to a first modified example. A magnetoresistance effect device 101 according to the first modified example shown in FIG. 18 is different from the magnetoresistance effect device 100 shown in FIG. 1 in that a magnetic material portion 50 is provided. In the magnetoresistance effect device 101 shown in FIG. 18, the same reference numerals will be given to the same components as those of the magnetoresistance effect device 100 shown in FIG. 1. Further, in the magnetoresistance effect device 101 according to the first modified example, the description of the configuration common to the magnetoresistance effect device 100 will be omitted.

The magnetic material portion 50 is located between the first signal line 20 and the magnetoresistance effect element 10. The magnetic material portion 50 is disposed to be separated from the first signal line 20 and the magnetoresistance effect element 10. For example, an insulator is provided between the magnetic material portion 50 and the first signal line 20 and between the magnetic material portion 50 and the magnetoresistance effect element 10.

The magnetic material portion 50 includes a soft magnetic material. The magnetic material portion 50 is, for example, a magnetic material having an insulating property. The magnetic material portion 50 is, for example, a ceramic such as ferrite. The magnetic material portion 50 is, for example, a rare earth iron garnet (RIG). Yttrium iron garnet (YIG) is an example of rare earth iron garnet (RIG). The magnetic material portion 50 may be, for example, a metal such as permalloy.

A high frequency magnetic field H_{rf1} which is generated from the first signal line 20 is applied to the magnetic material portion 50. The magnetization of the magnetic material portion 50 oscillates by receiving the high frequency magnetic field H_{rf1}. When the high frequency magnetic field H_{rf1} includes a signal of the frequency in the vicinity of the ferromagnetic resonance frequency of the magnetic material portion 50, the magnetization of the magnetic material portion 50 largely oscillates at that frequency. The oscillation of the magnetization of the magnetic material portion 50 causes a high frequency magnetic field H_{rf2}.

The high frequency magnetic field H_{rf}2 caused by the oscillation of the magnetization of the magnetic material portion 50 is applied to the first ferromagnetic layer 1. The magnetization of the first ferromagnetic layer 1 oscillates due to the high frequency magnetic field H_{rf}2 generated by the magnetic material portion 50. That is, the high frequency magnetic field H_{rf}2 caused by the high frequency magnetic field H_{rf}1 generated by the first high frequency current IR₁ flowing through the first signal line 20 is applied to the first ferromagnetic layer 1. The high frequency magnetic field H_{rf}2 generated by the magnetic material portion 50 is an example of the high frequency magnetic field caused by the first high frequency current IR₁ flowing through the first signal line 20.

The resistance R₁₀ of the magnetoresistance effect element 10 changes (oscillates) due to the oscillation of the magnetization of the first ferromagnetic layer 1. When the second high frequency signal is input to the second input port p2, the second high frequency current IR₂ flows through the second signal line 30. The second high frequency current IR₂ flows through the magnetoresistance effect element 10. The DC voltage V_{DC} which is the DC component of the voltage corresponding to the product of the resistance R₁₀ of the magnetoresistance effect element 10 and the current (the second high frequency current IR₂) flowing through the magnetoresistance effect element 10 is output from the output port p3. An example in which the magnetic material portion 50 is located between the first signal line 20 and the magnetoresistance effect element 10 has been described, but when the high frequency magnetic field H_{rf}1 generated by the first signal line 20 is applied to the magnetic material portion 50 and the high frequency magnetic field H_{rf}2 generated by the oscillation of the magnetization of the magnetic material portion 50 is applied to the first ferromagnetic layer 1, the position of the magnetic material portion 50 is not limited thereto. For example, the magnetic material portion 50 may be disposed so that the first signal line 20 is located between the magnetic material portion 50 and the magnetoresistance effect element 10. Further, when the plurality of magnetoresistance effect elements 10 are used, the high frequency magnetic field H_{rf}2 caused by the oscillation of the magnetization of one magnetic material portion 50 may be applied to the first ferromagnetic layers 1 of the plurality of magnetoresistance effect elements 10 or one magnetic material portion 50 may be provided for each magnetoresistance effect element 10 by using a plurality of magnetic material portions 50.

Since the magnetoresistance effect device 101 according to the first embodiment also oscillates the magnetization M1 of the first ferromagnetic layer 1 by the high frequency magnetic field H_{rf}2 caused by the first high frequency current IR₁, the amplitude of the oscillation of the magnetization M1 can be increased. When the amplitude of the oscillation of the magnetization M1 increases, the change amount (amplitude) of the resistance R₁₀ of the magnetoresistance effect element 10 increases and hence a large DC voltage V_{DC} can be output from the output port p3. Further, the magnetoresistance effect device 101 according to the first modified example can be used as the magnetic sensor, the rectifier, or the dielectric sensor that uses the dielectric as the object to be measured.

### SECOND MODIFIED EXAMPLE

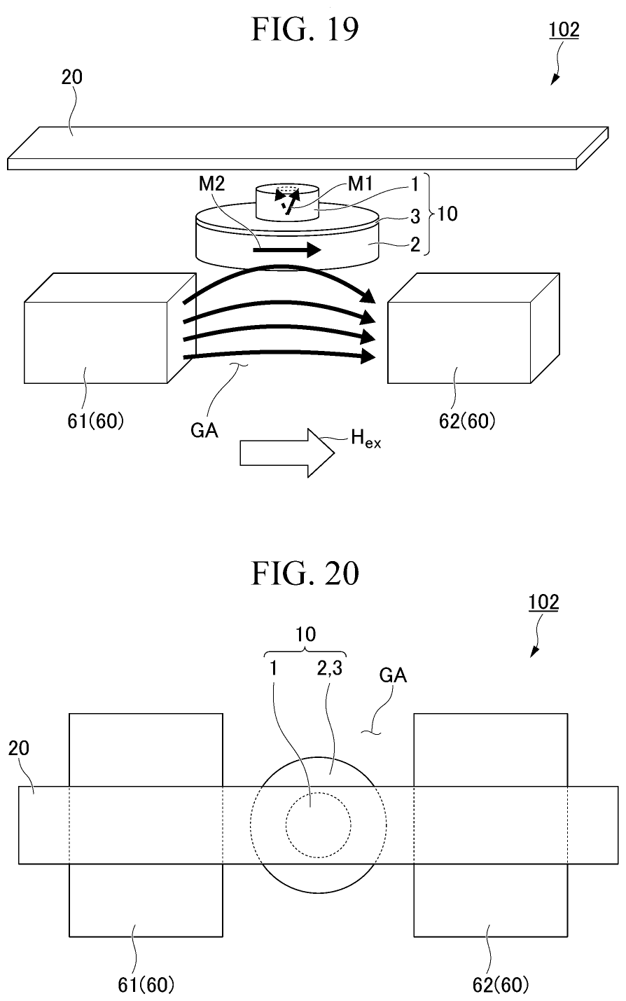

FIG. 19 is a perspective view showing the vicinity of the magnetoresistance effect element 10 of a magnetoresistance effect device 102 according to a second modified example. FIG. 20 is a plan view showing the vicinity of the magnetoresistance effect element 10 of the magnetoresistance effect device 102 according to the second modified example. In FIGS. 19 and 20, the second signal line 30 connected to the first ferromagnetic layer 1 and the line 42 connected to the second ferromagnetic layer 2 are omitted. The magnetoresistance effect device 102 according to the second modified example shown in FIGS. 19 and 20 is different from the magnetoresistance effect device 100 shown in FIG. 1 in that a yoke 60 is provided. In the magnetoresistance effect device 102 shown in FIGS. 19 and 20, the same reference numerals will be given to the same components as those of the magnetoresistance effect device 100 shown in FIG. 1. Further, in the magnetoresistance effect device 102 according to the second modified example, the description of the configuration common to the magnetoresistance effect device 100 will be omitted.

The yoke 60 is positioned closer to the second ferromagnetic layer 2 than the first ferromagnetic layer 1 in the lamination direction. The first ferromagnetic layer 1 of the magnetoresistance effect element 10 shown in FIGS. 19 and 20 is smaller than the second ferromagnetic layer 2 and is included in the second ferromagnetic layer 2 in the plan view in the lamination direction. For example, the yoke 60 is located on the side opposite to the first signal line 20 in the lamination direction with reference to the magnetoresistance effect element 10. The yoke 60 includes a soft magnetic material. The yoke 60 is, for example, Fe, Co, Ni, an alloy of Ni and Fe, an alloy of Fe and Co, an alloy of Fe, Co, and B, and the like.

The yoke 60 includes a first portion 61 and a second portion 62. The first portion 61 and the second portion 62 are separated from each other to form a gap GA. The first portion 61 and the second portion 62 sandwich the magnetoresistance effect element 10 in the gap in the plan view in the lamination direction. The magnetic flux line flows from the first portion 61 into the second portion 62 or from the second portion 62 into the first portion 61.

When the external magnetic field Hₑₓ is applied to the magnetoresistance effect device 102, the yoke 60 induces the magnetic flux and concentrates the magnetic flux in the gap GA between the first portion 61 and the second portion 62. The yoke 60 applies the magnetic field generated in the gap GA due to the external magnetic field Hₑₓ to the second ferromagnetic layer 2. The second ferromagnetic layer 2 is the second magnetization free layer and the magnetization M2 of the second ferromagnetic layer 2 changes its direction by receiving the magnetic field generated in the gap GA between the first portion 61 and the second portion 62. The direction of the magnetic field generated in the gap GA between the first portion 61 and the second portion 62 changes in response to the direction of the external magnetic field Hₑₓ. The magnetoresistance effect device 102 can be particularly applied to the magnetic sensor (see FIGS. 5(a) and 5(b)) that detects the direction of the external magnetic field Hₑₓ and uses the magnetoresistance effect element 10 of the first pattern.

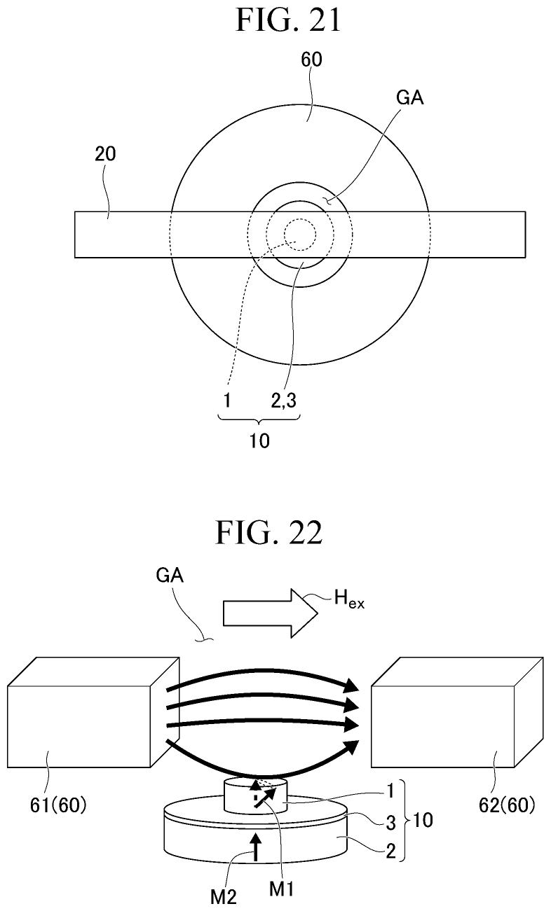

In the example shown in FIG. 19, the magnetoresi stance effect element 10 is not located in the gap GA of the yoke 60 in the lamination direction, but a part of the magnetoresistance effect element 10 (for example, a part or the entirety of the second ferromagnetic layer 2) may be located in the gap GA of the yoke 60 in the lamination direction. Further, in the example of FIG. 20, an example has been shown in which the first portion 61 and the second portion 62 of the yoke 60 sandwich the magnetoresistance effect element 10 in one direction, but as shown in FIG. 21, the yoke 60 may surround the periphery of the magnetoresistance effect element 10 in the plan view in the lamination direction.

Further, as shown in FIG. 22, the yoke 60 may be positioned closer to the first ferromagnetic layer 1 than the second ferromagnetic layer 2 in the lamination direction. FIG. 22 is a perspective view showing the vicinity of the magnetoresistance effect element 10 of the magnetoresistance effect device of another example of the second modified example. The yoke 60 applies the magnetic field generated in the gap GA due to the external magnetic field Hₑₓ to the first ferromagnetic layer 1. The rotation axis of the magnetization M1 of the first ferromagnetic layer 1 is inclined by receiving the magnetic field generated in the gap GA between the first portion 61 and the second portion 62. The direction of the magnetic field generated in the gap GA between the first portion 61 and the second portion 62 changes in response to the direction of the external magnetic field Hₑₓ. The magnetoresistance effect device shown in FIG. 22 can be particularly applied to the magnetic sensor (see FIGS. 6(a) and 6(b)) that detects the direction of the external magnetic field Hₑₓ and uses the magnetoresistance effect element 10 of the second pattern .

In the example shown in FIG. 22, the magnetoresistance effect element 10 is not located in the gap GA of the yoke 60 in the lamination direction, but a part of the magnetoresistance effect element 10 (for example, a part or the entirety of the first ferromagnetic layer 1) may be located in the gap GA of the yoke 60 in the lamination direction. Further, also in the example shown in FIG. 22, the yoke 60 may surround the periphery of the magnetoresistance effect element 10 in the plan view in the lamination direction.

### THIRD MODIFIED EXAMPLE

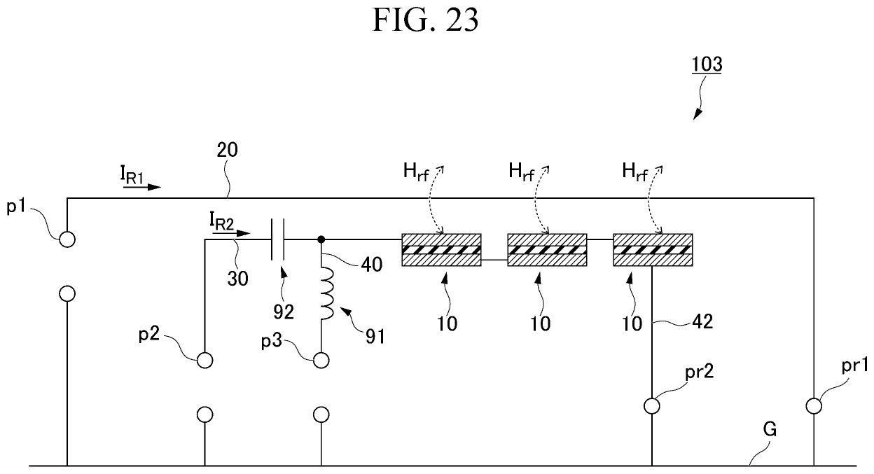

FIG. 23 is a diagram schematically showing a circuit configuration of a magnetoresistance effect device 103 according to a third modified example. The magnetoresistance effect device 103 according to the third modified example shown in FIG. 23 is different from the magnetoresistance effect device 100 shown in FIG. 1 in that the plurality of magnetoresistance effect elements 10 are provided. In the magnetoresistance effect device 103 shown in FIG. 23, the same reference numerals will be given to the same components as those of the magnetoresistance effect device 100 shown in FIG. 1. Further, in the magnetoresistance effect device 103 according to the third modified example, the description of the configuration common to the magnetoresistance effect device 100 will be omitted.

Each of the magnetoresistance effect elements 10 is connected to the second signal line 30 and the magnetoresistance effect elements 10 are connected in series to each other. Each of the magnetoresi stance effect element 10 is separated from the first signal line 20 via the insulator. The first signal line 20 is disposed at a position in which the high frequency magnetic field H_{rf} caused by the first high frequency current IR₁ flowing through the first signal line 20 can be applied to the first ferromagnetic layer 1 of each magnetoresistance effect element 10. The high frequency magnetic field H_{rf} caused by the first high frequency current IR₁ flowing through the first signal line 20 is applied to each of the first ferromagnetic layers 1. The second ferromagnetic layer 2 of each of the magnetoresistance effect elements 10 functions as the magnetization fixed layer. The magnetization directions of the second ferromagnetic layers 2 of the plurality of magnetoresistance effect elements 10 are the same directions.

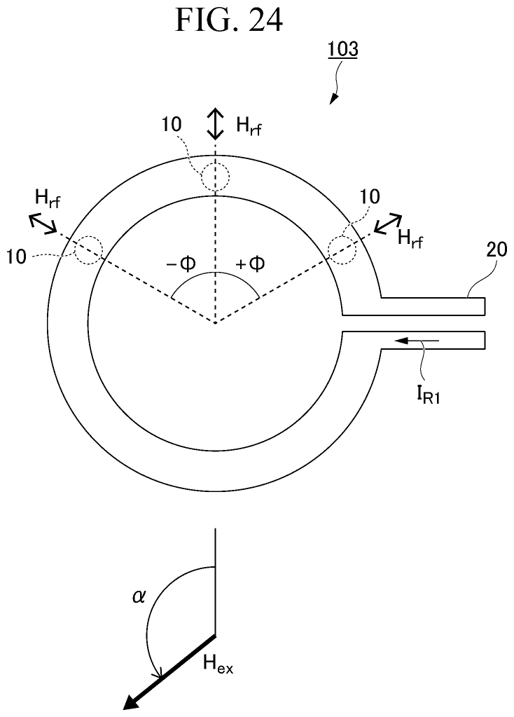

FIG. 24 is a plan view of the vicinity of the magnetoresistance effect element 10 of the magnetoresistance effect device 103 according to the third modified example. Only the magnetoresistance effect element 10 and the first signal line 20 are shown in FIG. 24. A part of the first signal line 20 shown in FIG. 24 has an annular shape in the plan view in the lamination direction. Each of the magnetoresistance effect elements 10 is located at a position overlapping the first signal line 20 in the plan view in the lamination direction. As shown in FIG. 24, the magnetoresistance effect elements 10 are located at positions different by a rotation angle φ along the first signal line 20 having an annular shape. The rotation angle φ is, for example, 60°. In FIG. 24, an angle α is an angle which is formed by the reference direction and the direction of the external magnetic field Hₑₓ. In FIG. 24, as an example, a direction in which the high frequency magnetic field H_{rf} is applied to one magnetoresistance effect element 10 of three magnetoresistance effect elements 10 is set as the reference direction.

The high frequency magnetic field H_{rf} is generated around the first signal line 20 according to the right-handed screw rule. The directions of the high frequency magnetic fields H_{rf} applied to the first ferromagnetic layers 1 of the magnetoresistance effect elements 10 are different in the plurality of magnetoresistance effect elements 10. As shown in FIG. 24, the direction of the high frequency magnetic field H_{rf} applied to the first ferromagnetic layer 1 of each of the magnetoresistance effect elements 10 shifts by the same angle as the rotation angle φ between the adjacent magnetoresistance effect elements 10. The magnetoresistance effect device 103 can be particularly applied to the magnetic sensor (see FIGS. 5(a) and 5(b)) that detects the direction of the external magnetic field Hₑₓ and uses the magnetoresistance effect element 10 of the first pattern and the magnetic sensor (see FIGS. 6(a) and 6(b)) that uses the magnetoresistance effect element 10 of the second pattern.

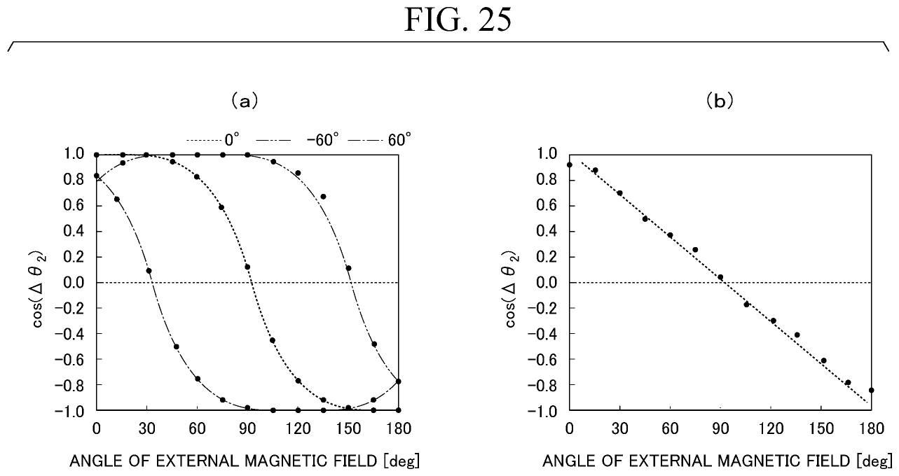

Since the relative angle between the direction of the high frequency magnetic field H_{rf} applied to the first ferromagnetic layer 1 and the magnetization direction of the second ferromagnetic layer 2 in each of the magnetoresistance effect elements 10 is different in the plurality of magnetoresistance effect elements 10, the phase difference Δθ₂ in each of the magnetoresistance effect elements 10 is different in the plurality of magnetoresistance effect elements 10. FIG. 25(a) is a graph showing a change in cos(Δθ₂) of each of the magnetoresistance effect elements 10 with respect to the change of the direction of the external magnetic field Hₑₓ and FIG. 25(b) is a graph showing a change in arithmetical mean in cos(Δθ₂) of three magnetoresistance effect elements 10. FIGS. 25(a) and 25(b) are graphs when three magnetoresistance effect elements 10 are arranged at positions different by the rotation angle of 60° along the first signal line 20 having an annular shape. The numbers of the legend of the graph of FIG. 25(a) are the values of the rotation angles φ of the magnetoresistance effect elements 10.

As shown in the graph of FIG. 25(a), the change in cos(Δθ₂) of each of the magnetoresistance effect elements 10 is not very linear with respect to the change in the direction of the external magnetic field Hₑₓ. The DC voltage output from each magnetoresistance effect element 10 is proportional to cos(Δθ₁) of each magnetoresistance effect element 10. When the phase difference between the second high frequency current IR₂ and the first high frequency current IR₁ is Δθ₃, Δθ₁=Δθ₂+Δθ₃ is established. Accordingly, the DC voltage output from the magnetoresistance effect element 10 in each magnetoresistance effect element 10 is proportional to cos(Δθ₂+Δθ₃). Since the phase difference Δθ₃ is constant, the linearity of the change of cos(Δθ₂+Δθ₃) with respect to the change of the direction of the external magnetic field Hₑₓ in each magnetoresistance effect element 10 is the same as that of cos(Δθ₂). Thus, the linearity of the change of the DC voltage output from each magnetoresistance effect element 10 with respect to the change of the direction of the external magnetic field Hₑₓ is not very linear.

In contrast, as shown in the graph of FIG. 25(b), the linearity of the change in the value obtained by adding cos(Δθ₂) of three magnetoresistance effect elements 10 (the value obtained by adding cos(Δθ₂+Δθ₃) of three magnetoresistance effect elements 10) with respect to the change of the direction of the external magnetic field Hₑₓ is good. Since the DC voltage V_{DC} output from the output port p3 is proportional to the value obtained by adding cos(Δθ₂+Δθ₃) of three magnetoresistance effect elements 10, the linearity of the change of the DC voltage V_{DC} with respect to the change of the direction of the external magnetic field Hₑₓ is good.

In the examples shown in FIGS. 23 to 25, an example in which the directions of the high frequency magnetic fields H_{rf} applied to the first ferromagnetic layers of three magnetoresistance effect elements 10 are different from each other has been described, but when the directions of the high frequency magnetic fields H_{rf} applied to the first ferromagnetic layers of at least two magnetoresistance effect elements 10 are different from each other, it is possible to obtain a constant effect that the linearity of the change of the DC voltage V_{DC} with respect to the change of the direction of the external magnetic field Hₑₓ is good. When the directions of the high frequency magnetic fields H_{rf} applied to the first ferromagnetic layers of at least three magnetoresistance effect elements 10 are different from each other, the linearity of the change of the DC voltage V_{DC} with respect to the change of the direction of the external magnetic field Hₑₓ can be further increased.

Further, the magnitude of the high frequency magnetic field H_{rf} applied to the first ferromagnetic layer of each magnetoresistance effect element 10 may be different in the plurality of magnetoresistance effect elements 10 in order to improve the linearity of the change of the DC voltage V_{DC} with respect to the change of the direction of the external magnetic field Hₑₓ. For example, the distance between the first signal line 20 and the first ferromagnetic layer of each magnetoresistance effect element 10 may be different in the plurality of magnetoresistance effect elements 10.

### FOURTH MODIFIED EXAMPLE

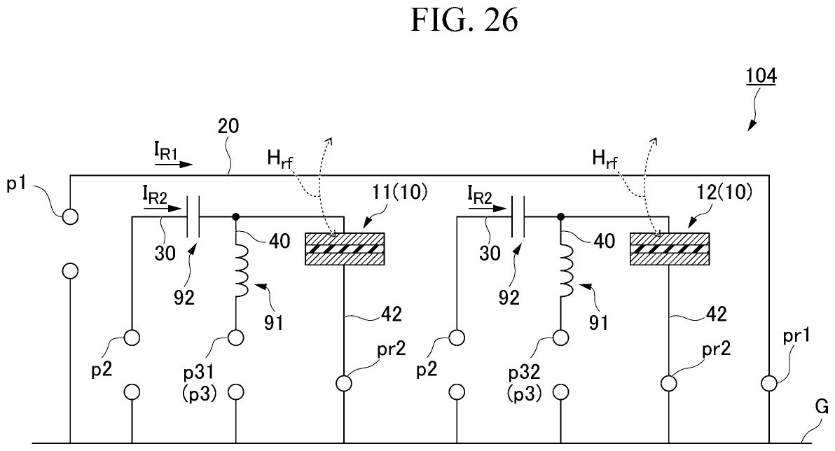

FIG. 26 is a diagram schematically showing a circuit configuration of a magnetoresistance effect device 104 according to a fourth modified example. The magnetoresistance effect device 104 according to the fourth modified example shown in FIG. 26 is different from the magnetoresistance effect device 100 shown in FIG. 1 in that a plurality of second input ports p2, a plurality of output ports p3, the plurality of magnetoresistance effect elements 10, and the like are provided. In the magnetoresistance effect device 104 shown in FIG. 26, the same reference numerals will be given to the same components as those of the magnetoresistance effect device 100 shown in FIG. 1. Further, in the magnetoresistance effect device 104 according to the fourth modified example, the description of the configuration common to the magnetoresistance effect device 100 will be omitted.

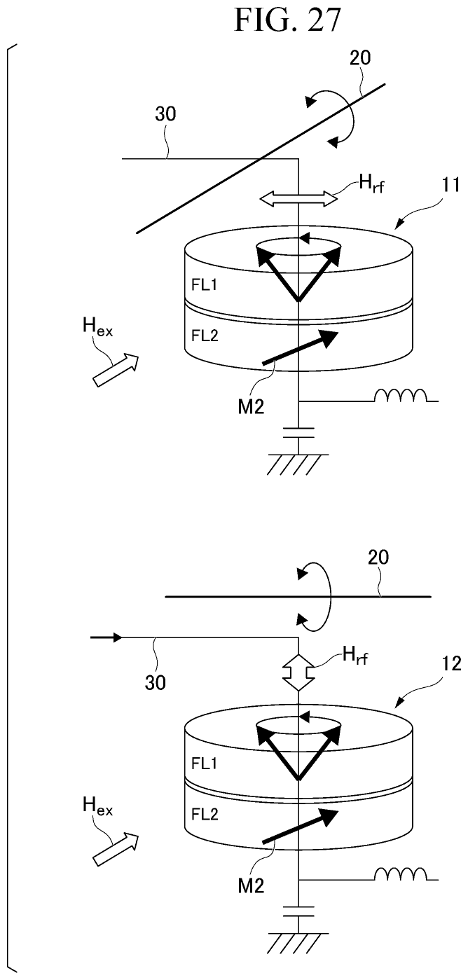

FIG. 27 is an enlarged perspective view positioned closer to the magnetoresistance effect element 10 of the magnetoresistance effect device 104 according to the fourth modified example. Two magnetoresistance effect elements 10 are provided and are respectively referred to as a first magnetoresistance effect element 11 and a second magnetoresistance effect element 12.

As an example, the configurations of the first magnetoresistance effect element 11 and the second magnetoresistance effect element 12 are the same as those of the first pattern shown in FIGS. 5(a) and 5(b). Specifically, in each of the first magnetoresistance effect element 11 and the second magnetoresistance effect element 12, both the first ferromagnetic layer 1 and the second ferromagnetic layer 2 are the magnetization free layers in which the magnetization directions change and the magnetization M1 of the first ferromagnetic layer 1 oscillates (in a precession manner) due to the high frequency magnetic field H_{rf}. The configurations of the first magnetoresistance effect element 11 and the second magnetoresistance effect element 12 may be the same as those of the second pattern shown in FIGS. 6(a) and 6(b).

The external magnetic field Hₑₓ is applied to each of the first magnetoresistance effect element 11 and the second magnetoresistance effect element 12. The external magnetic field Hₑₓ is applied from a direction inclined with respect to the lamination direction of the first magnetoresistance effect element 11 or the second magnetoresistance effect element 12. The orientation direction of the magnetization of the second ferromagnetic layer 2 coincides with, for example, the application direction of the external magnetic field Hₑₓ.

The first signal line 20 is separated from each of the first magnetoresistance effect element 11 and the second magnetoresistance effect element 12 with an insulator interposed therebetween. The first signal line 20 extends in the first extension direction at a position overlapping the first magnetoresistance effect element 11 in the plan view in the lamination direction of the first magnetoresistance effect element 11. The first signal line 20 extends in the second extension direction at a position overlapping the second magnetoresistance effect element 12 in the plan view in the lamination direction of the second magnetoresistance effect element 12. The first extension direction and the second extension direction are different from each other and an angle formed therebetween is 90°.

The first magnetoresistance effect element 11 and the second magnetoresistance effect element 12 are respectively connected to different output ports p3. Hereinafter, the output port p3 from which a voltage caused by the output from the first magnetoresistance effect element 11 is output will be referred to as a first output port p31 and the output port p3 from which a voltage caused by the output from the second magnetoresistance effect element 12 is output will be referred to as a second output port p32.

As described above, a voltage V1 output from the first magnetoresistance effect element 11 is expressed by the product of the resistance R₁₁ of the first magnetoresistance effect element 11 and the current (the second high frequency current IR₂) flowing through the first magnetoresistance effect element 11 and satisfies the following relationship.

IR₂=A·sin(2πft)

R₁₁=B·sin(2πft+Δθ₁)+R₀

V1=IR₂×R₁₁=(A B/2)·{cos(Δθ₁)−cos(4πft+Δθ₁)}+A·R₀·sin(2πft)

(A·B/2)·cos(Δθ₁) which is the DC component of the voltage V1 is output from the first output port p31.

In contrast, the oscillation direction of the high frequency magnetic field H_{rf} applied to the second magnetoresistance effect element 12 is inclined by 90° with respect to the oscillation direction of the high frequency magnetic field H_{rf} applied to the first magnetoresistance effect element 11. Thus, the phase delay of the resistance R₁₂ of the second magnetoresistance effect element 12 with respect to the resistance R₁₁ of the first magnetoresistance effect element 11 is π/2(90°)

As a result, a voltage V2 output from the second magnetoresistance effect element 12 satisfies the following relationship.

IR₂=A·sin(2πft)

R₁₂=B·sin(2πft+Δθ₁−π/2)+R₀=−B·cos(2πft+Δθ₁)+R₀

V2=IR₂×R₁₂=(A·B/2)·{sin(Δθ₁)−sin(4πft+Δθ₁)}+A·R₀·sin(2πft)

(A·B/2)·sin(Δθ₁) which is the DC component of the voltage V2 is output from the second output port p32.

When the DC component of the voltage V1 output from the first output port p31 and the DC component of the voltage V2 output from the second output port p32 are used, specific values of (A·B/2) and Δθ₁ can be obtained. Additionally, specific values of (A·B/2) and AO1 can be obtained by using “−(A·B/2)·cos(4πft+Δθ₁)” which is the high-frequency component of the voltage V1 and “−(A·B/2)·sin(4πft+Δθ₁)” which is the high-frequency component of the voltage V2.

The magnitude of the external magnetic field can be detected from, for example, the value of (A·B/2). This is because the value of (A·B/2) changes when the magnitude of the external magnetic field Hₑₓ changes. Specifically, when the magnitude of the external magnetic field Hₑₓ changes, the inclination angle of the rotation axis of the magnetization M1 of the first ferromagnetic layer 1 with respect to the lamination direction changes. As a result, an amplitude B of the resistance value R₁₁ of the first magnetoresistance effect element 11 and an amplitude B of the resistance value R₁₂ of the second magnetoresistance effect element 12 changes so that the value of (A·B/2) changes.

Further, the angle of the external magnetic field Hₑₓ can be detected from, for example, Δθ₁. This is because the direction of the magnetization M2 of the second ferromagnetic layer 2 with respect to the rotation axis of the magnetization M1 of the first ferromagnetic layer 1 changes and the phase difference Δθ₁ changes when the angle of the external magnetic field Hₑₓ changes similarly to the first pattern shown in FIGS. 5(a) and 5(b). When the configurations of the first magnetoresistance effect element 11 and the second magnetoresistance effect element 12 are the same as the second pattern shown in FIGS. 6(a) and 6(b), the inclination direction of the rotation axis of the magnetization M1 changes in response to the change of the direction of the external magnetic field Hₑₓ and the phase difference Δθ₁ changes similarly to the second pattern. Additionally, in the case of the fourth modified example, the value of Δθ₁ itself can be obtained and the direction of the external magnetic field can be detected throughout 360° in the in-plane direction.

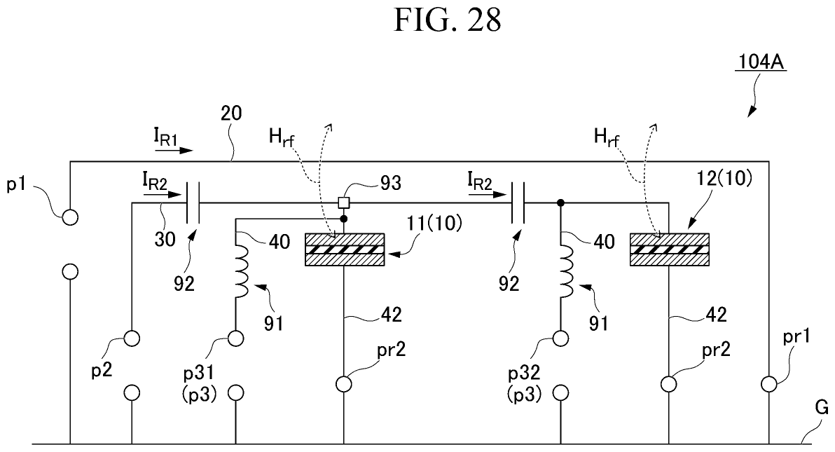

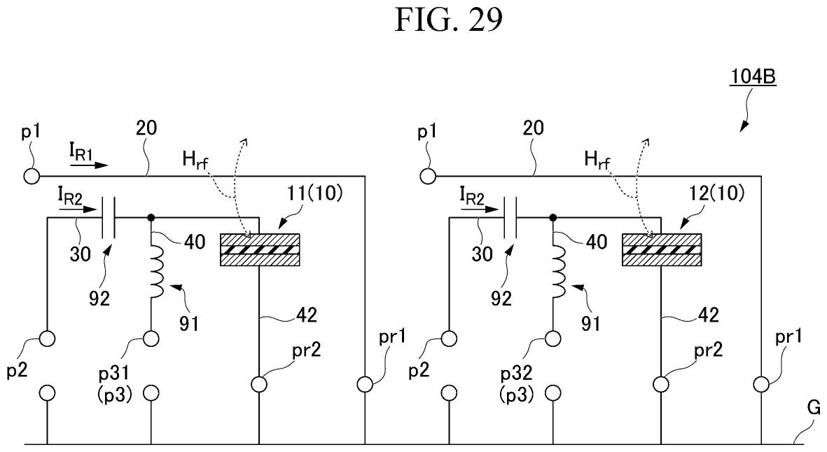

In FIG. 26, an example has been shown in which two second input ports p2 are provided and the second input ports p2 are respectively connected to the first magnetoresistance effect element 11 and the second magnetoresistance effect element 12, but one second input port p2 may be provided as in a magnetoresistance effect device 104A shown in FIG. 28. The second input port p2 in FIG. 28 is connected to the first magnetoresistance effect element 11 and the second magnetoresistance effect element 12. A directional coupler 93 is provided between the first magnetoresistance effect element 11 and the second magnetoresistance effect element 12. Further, as in a magnetoresistance effect device 104B shown in FIG. 29, a plurality of first signal lines 20 may be provided. In FIG. 29, the first signal line 20 applying the high frequency magnetic field H_{rf} to the first magnetoresistance effect element 11 is different from the first signal line 20 applying the high frequency magnetic field H_{rf} to the second magnetoresistance effect element 12.

So far, some modified examples of the magnetoresistance effect device according to the first embodiment have been described. The modified examples of the magnetoresistance effect device according to the first embodiment are not limited thereto and the modified examples may be combined with each other. For example, the magnetic material portion 50 of the first modified example may be provided in the second modified example or the third modified example and the high frequency magnetic field H_{rf}2 caused by the oscillation of the magnetization of the magnetic material portion 50 may be applied to the first ferromagnetic layer 1. Further, the yoke 60 of the second modified example may be provided in each magnetoresistance effect element 10 of the third modified example and the magnetic field generated in the gap GA may be applied to the first ferromagnetic layer 1 or the second ferromagnetic layer 2 of each magnetoresistance effect element 10.

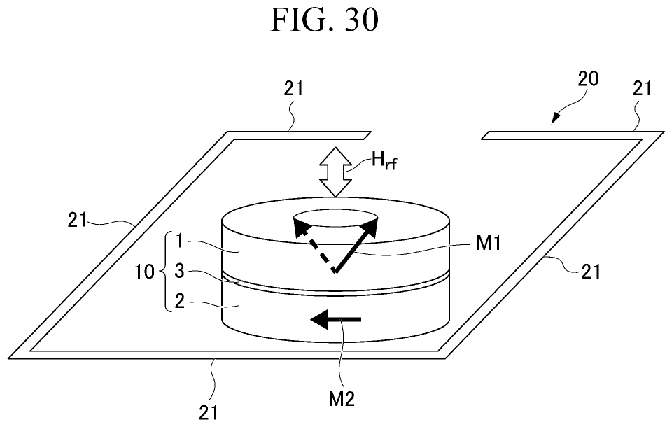

Further, as shown in FIG. 30, the high frequency magnetic field H_{rf} may be applied in the lamination direction of the first ferromagnetic layer 1. FIG. 30 is a perspective view showing the vicinity of the magnetoresistance effect element 10 of the magnetoresistance effect device according to the fifth modified example.

The first signal line 20 includes an extension portion 21. The extension portion 21 extends in a direction intersecting the lamination direction in the plan view in the lamination direction of the magnetoresistance effect element 10. The extension portion 21 is located at a position not overlapping the magnetoresistance effect element 10 in the plan view in the lamination direction. Further, a part of the extension portion 21 overlaps the magnetoresistance effect element 10 in the plan view in the direction perpendicular to the lamination direction. The magnetoresistance effect element 10 is not disposed at the end where the extension direction of the extension portion 21 is extended. That is, the extension portion 21 is disposed not to overlap the magnetoresistance effect element 10 when viewed from the extension direction. The first signal line 20 surrounds, for example, the periphery of the first ferromagnetic layer 1 in the plan view in the lamination direction of the magnetoresistance effect element 10.

When the high frequency current flows through the extension portion 21, the high frequency magnetic field H_{rf} is generated. The high frequency magnetic field H_{rf} is applied to the first ferromagnetic layer 1. The high frequency magnetic field H_{rf} is applied to the first ferromagnetic layer 1 from a direction intersecting the in-plane where the first ferromagnetic layer 1 extends. The high frequency magnetic field H_{rf} is applied to, for example, the first ferromagnetic layer 1 in the lamination direction. In this case, the magnetization M2 of the second ferromagnetic layer 2 includes a component of the in-plane direction in which the second ferromagnetic layer 2 extends. The magnetization M2 of the second ferromagnetic layer 2 is oriented, for example, in one direction of the in-plane direction. Also, in the configuration, the magnetoresistance effect device is operated.

### Second Embodiment

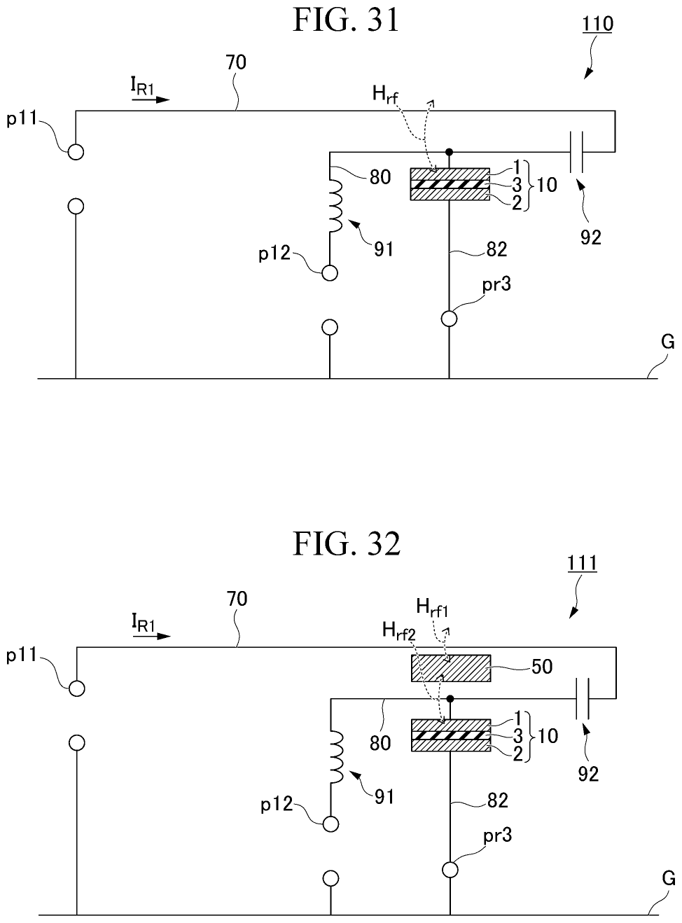

FIG. 31 is a diagram showing a circuit configuration of a magnetoresistance effect device according to a second embodiment. A magnetoresistance effect device 110 includes the magnetoresistance effect element 10, a first input port p11, a first signal line 70, and an output port p12. The magnetoresistance effect device 110 shown in FIG. 31 further includes lines 80 and 82, a reference potential terminal pr3, an inductor 91, and a capacitor 92. In the magnetoresistance effect device 110 shown in FIG. 31, the same reference numerals will be given to the same components as those of the magnetoresistance effect device 100 shown in FIG. 1. Further, in the magnetoresistance effect device 110 according to the second embodiment, the description of the configuration common to the magnetoresistance effect device 100 will be omitted.

The first input port p11 is an input terminal of the magnetoresistance effect device 110. For example, an AC signal source, an antenna, or the like is connected to the first input port p11. The first input port p11 is connected to the first signal line 70. The first input port p11 is connected to, for example, the end portion of the first signal line 70. The first high frequency signal is input to the first input port p11 and the first high frequency signal is input from the first input port p11 to the first signal line 70. The first high frequency signal causes the first high frequency current IR₁ in the first signal line 70.

The first signal line 70 is a signal line through which the first high frequency current IR₁ flows. The first signal line 70 shown in FIG. 31 is a line which connects the first input port p11 and the magnetoresistance effect element 10 to each other. The first signal line 70 shown in FIG. 31 electrically connects the first input port p11 and the magnetoresistance effect element 10 to each other.

The first signal line 70 is disposed at a position in which the high frequency magnetic field H_{rf} caused by the first high frequency current IR₁ flowing through the first signal line 70 can be applied to the first ferromagnetic layer 1. The high frequency magnetic field H_{rf} caused by the first high frequency current IR₁ flowing through the first signal line 70 is applied to the first ferromagnetic layer 1. The magnetization of the first ferromagnetic layer 1 oscillates due to the high frequency magnetic field H_{rf} applied to the first ferromagnetic layer 1. When the frequency of the high frequency magnetic field H_{rf} applied to the first ferromagnetic layer 1 is in the vicinity of the ferromagnetic resonance frequency of the first ferromagnetic layer 1, the magnetization of the first ferromagnetic layer 1 largely oscillates. A portion in which the high frequency magnetic field H_{rf} applied to the first ferromagnetic layer 1 is mainly generated in the first signal line 20 is, for example, positioned closer to the first ferromagnetic layer 1 than the second ferromagnetic layer 2.

Further, the first signal line 70 is connected to the magnetoresistance effect element 10. The first high frequency current IR₁ flowing through the first signal line 70 flows through the magnetoresistance effect element 10. The amplitude of the oscillation of the magnetization of the first ferromagnetic layer 1 due to the high frequency magnetic field H_{rf} applied to the first ferromagnetic layer 1 is larger than the amplitude of the oscillation of the magnetization of the first ferromagnetic layer 1 due to the spin transfer torque generated by the first high frequency current IR₁ flowing through the magnetoresistance effect element 10.

The output port p12 is an output terminal of the magnetoresistance effect device 110. For example, a voltmeter for monitoring a voltage or an ammeter for monitoring a current is connected to the output port p12. The output port p12 shown in FIG. 31 is connected to the line 80 branching from the first signal line 70. A signal component (DC voltage or DC current) caused by the output from the magnetoresistance effect element 10 is output from the output port p12.

The line 80 is a line branching from the first signal line 70. The line 80 connects the first signal line 70 and the output port p12 to each other. The line 82 connects the magnetoresistance effect element 10 and the reference potential terminal pr3 to each other.

Further, the inductor 91 in FIG. 31 is located on the line 80. The inductor 91 suppresses the first high frequency current IR₁ and the high-frequency component of the output from the magnetoresistance effect element 10 from reaching the output port p12. The capacitor 92 in FIG. 31 is located on the first signal line 70. The capacitor 92 in FIG. 31 is located between the first input port p11 and the branch point of the first signal line 70 with the line 82.

Next, an operation of the magnetoresistance effect device 110 will be described. Hereinafter, in the second embodiment, an example of the DC voltage which is the DC signal component output from the output port p12 will be described. When the first high frequency signal is input to the first input port p11, the first high frequency current IR₁ reaches the first signal line 70. The first high frequency current IR₁ causes the high frequency magnetic field H_{rf}. The high frequency magnetic field H_{rf} is applied to the first ferromagnetic layer 1 of the magnetoresi stance effect element 10.

The magnetization of the first ferromagnetic layer 1 oscillates by receiving the high frequency magnetic field H_{rf} caused by the first high frequency current IR₁. The resistance R₁₀ of the magnetoresistance effect element 10 changes (oscillates) as the magnetization of the first ferromagnetic layer 1 oscillates.

Further, the first high frequency current IR₁ flows through the magnetoresistance effect element 10. The DC voltage V_{DC} is output from the output port p12. The DC voltage V_{DC} is the DC component of the voltage V (the output voltage from the magnetoresistance effect element 10) which is the product of the resistance R₁₀ of the magnetoresistance effect element 10 and the current (the first high frequency current IR₁) flowing through the magnetoresistance effect element 10.

The magnetoresistance effect device 110 of the second embodiment can be used as the magnetic sensor or the rectifier similarly to the magnetoresistance effect device 100 of the first embodiment. Further, even when the magnetoresistance effect device 110 of the second embodiment is used as the magnetic sensor, it is possible to detect the change of the magnitude of the external magnetic field, the magnitude of the external magnetic field, or the direction of the external magnetic field similarly to the first embodiment.

An operation as the magnetic sensor and the rectifier in the magnetoresistance effect device 110 of the second embodiment is substantially the same as that of the magnetoresistance effect device 100 of the first embodiment. However, since the first signal line 70 is connected to the magnetoresistance effect element 10 and the first high frequency current IR₁ flowing through the first signal line 70 flows through the magnetoresistance effect element 10, the second high frequency current IR₂ flowing through the magnetoresistance effect element 10 of the first embodiment is replaced with the first high frequency current IR₁ flowing through the magnetoresistance effect element 10 of the second embodiment. The phase difference Δθ₁ of the first embodiment is replaced with the phase difference Δθ₂ between the phase of the first high frequency current IR₁ and the phase of the resistance R₁₀ of the magnetoresistance effect element 10 and the DC voltage V_{DC} c is expressed by (A·B/2)·cos(Δθ₂).

In the magnetoresistance effect device 110 according to the second embodiment, since the magnetization of the first ferromagnetic layer 1 oscillates due to the high frequency magnetic field H_{rf} caused by the first high frequency current IR₁, the amplitude of the oscillation of the magnetization can be increased. When the amplitude of the oscillation of the magnetization increases, the change amount (amplitude) of the resistance R₁₀ of the magnetoresistance effect element 10 increases and hence a large DC voltage V_{DC} can be output from the output port p12. Further, the magnetoresistance effect device 110 according to the second embodiment can be used as the magnetic sensor or the rectifier.

Although the second embodiment has been described with reference to the drawings, each configuration in the second embodiment and a combination thereof are examples and the configuration can be added, omitted, replaced, and modified in other forms without departing from the spirit of the present disclosure. For example, in the second embodiment, the magnetoresistance effect element 10 is one example. However, the plurality of magnetoresistance effect elements 10 may be connected to the first signal line 20 so that the first high frequency current IR₁ flows through the plurality of magnetoresistance effect elements 10 and the high frequency magnetic field H_{rf} caused by the first high frequency current IR₁ flowing through the first signal line 20 may be applied to the first ferromagnetic layers 1 of the plurality of magnetoresistance effect elements 10.

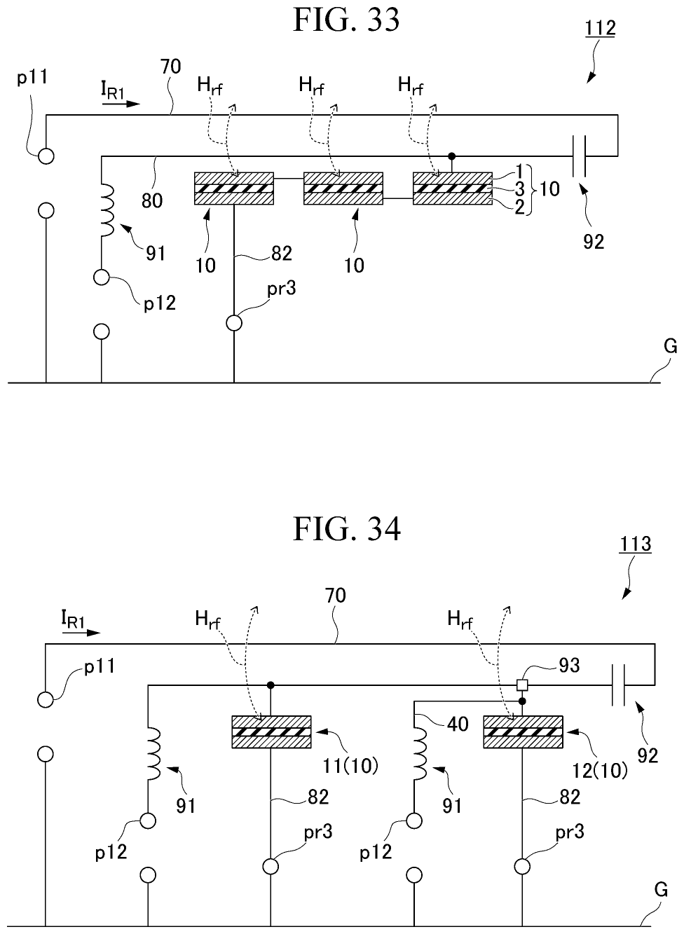

For example, also in the second embodiment, the same modifications and modified examples as those of the first embodiment can be applied and the modifications and modified examples can be combined with each other. For example, as in a magnetoresistance effect device 111 shown in FIG. 32, the magnetic material portion 50 may be provided and the high frequency magnetic field generated by the oscillation of the magnetization of the magnetic material portion 50 may be applied to the first ferromagnetic layer 1. Further, for example, as in a magnetoresistance effect device 112 shown in FIG. 33, the plurality of magnetoresistance effect elements 10 may be provided and the direction of the high frequency magnetic field H_{rf} applied to the first ferromagnetic layer 1 of each of the magnetoresistance effect elements 10 may be different in the plurality of magnetoresistance effect elements 10 similarly to the third modified example of the first embodiment. In the magnetoresistance effect device 112 shown in FIG. 33, each of the magnetoresistance effect elements 10 is connected to the first signal line 70 and the magnetoresistance effect elements 10 are connected in series to each other.

Further, for example, as in a magnetoresistance effect device 113 shown in FIG. 34, the plurality of magnetoresistance effect elements may be provided (the first magnetoresistance effect element 11 and the second magnetoresistance effect element 12 may be provided) and an angle formed by the first extension direction and the second extension direction may be 90° similarly to the fourth modified example of the first embodiment.

### Third Embodiment

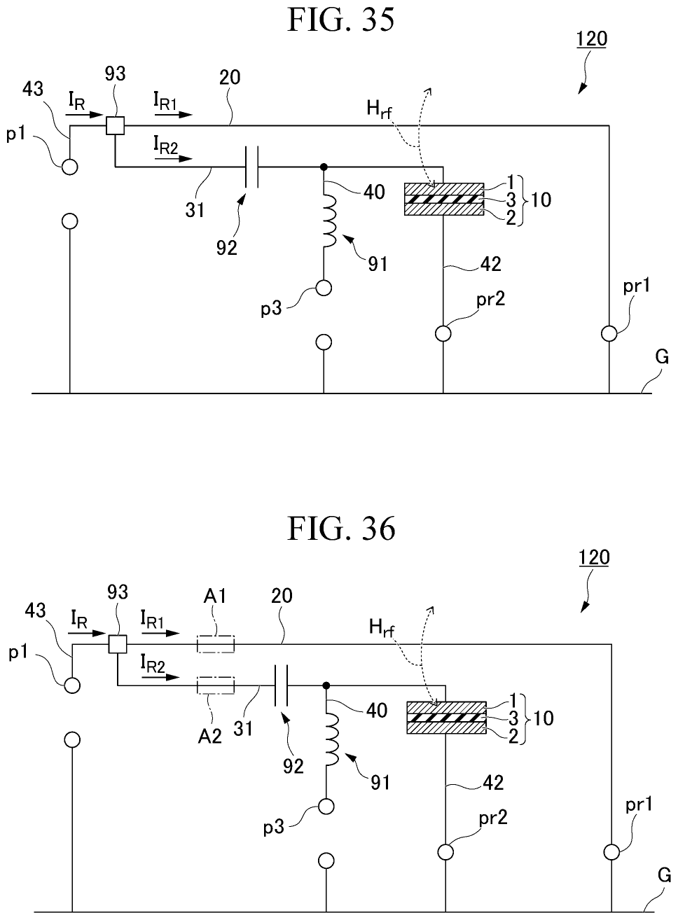

FIG. 35 is a diagram showing a circuit configuration of a magnetoresistance effect device according to a third embodiment. A magnetoresistance effect device 120 includes the magnetoresistance effect element 10, the first input port p1, the first signal line 20, a second signal line 31, a line 43, the directional coupler 93, and the output port p3. The magnetoresistance effect device 120 shown in FIG. 35 is different from the magnetoresistance effect device 100 shown in FIG. 1 in that the first signal line 20 and the second signal line 31 are connected to the first input port p1 via the line 43 and the directional coupler 93 and the second input port p2 is not provided. In the magnetoresistance effect device 120 shown in FIG. 35, the same reference numerals will be given to the same components as those of the magnetoresistance effect device 100 shown in FIG. 1. Further, in the magnetoresistance effect device 120 according to the third embodiment, the description of the configuration common to the magnetoresistance effect device 100 will be omitted.

The second signal line 31 is connected to the first input port p1 and the magnetoresistance effect element 10. In the example shown in FIG. 35, the first input port p1 is connected to the first signal line 20 and the second signal line 31 via the line 43 and the directional coupler 93 and the first high frequency signal which generates the first high frequency current IR₁ in the first signal line 20 and generates the second high frequency current IR₂ in the second signal line 31 is input to the first input port p1. The second high frequency current IR₂ flowing through the second signal line 31 flows through the magnetoresistance effect element 10.

Next, an operation of the magnetoresistance effect device 120 will be described. Hereinafter, an example of the DC voltage which is the DC signal component output from the output port p3 in the second embodiment will be described.

When the first high frequency signal is input to the first input port p1, the high frequency current I_{R} flows through the line 43. The high frequency current IR branches to the first signal line 20 and the second signal line 30 by the directional coupler 93, the first high frequency current IR₁ flows through the first signal line 20, and the second high frequency current IR₂ flows through the second signal line 31. The first high frequency current IR₁ causes the high frequency magnetic field H_{rf}. The high frequency magnetic field H_{rf} is applied to the first ferromagnetic layer 1 of the magnetoresistance effect element 10.

The magnetization of the first ferromagnetic layer 1 oscillates by receiving the high frequency magnetic field H_{rf} caused by the first high frequency current IR₁. The resistance R₁₀ of the magnetoresistance effect element 10 changes (oscillates) as the magnetization of the first ferromagnetic layer 1 oscillates. The amplitude of the oscillation of the magnetization of the first ferromagnetic layer 1 due to the high frequency magnetic field H_{rf} applied to the first ferromagnetic layer 1 is larger than the amplitude of the oscillation of the magnetization of the first ferromagnetic layer 1 due to the spin transfer torque generated by the second high frequency current IR₂ flowing through the magnetoresistance effect element 10.

The second high frequency current IR₂ flows through the magnetoresistance effect element 10. The DC voltage V_{DC} is output from the output port p3. The DC voltage V_{DC} is the DC component of the voltage V (the output voltage from the magnetoresistance effect element 10) which is the product of the resistance R₁₀ of the magnetoresistance effect element 10 and the current (the second high frequency current IR₂) flowing through the magnetoresistance effect element 10.

The magnetoresistance effect device 120 of the third embodiment can be used as the magnetic sensor or the rectifier similarly to the magnetoresistance effect device 100 of the first embodiment. Further, even when the magnetoresistance effect device 120 of the third embodiment is used as the magnetic sensor, it is possible to detect the change of the magnitude of the external magnetic field, the magnitude of the external magnetic field, or the direction of the external magnetic field similarly to the first embodiment.

An operation as the magnetic sensor and the rectifier in the magnetoresistance effect device 120 of the third embodiment is substantially the same as that of the magnetoresistance effect device 100 according to the first embodiment.

In the magnetoresistance effect device 120 according to the third embodiment, since the magnetization of the first ferromagnetic layer 1 oscillates due to the high frequency magnetic field H_{rf} caused by the first high frequency current IR₁, the amplitude of the oscillation of the magnetization can be increased. When the amplitude of the oscillation of the magnetization increases, the change amount (amplitude) of the resistance R₁₀ of the magnetoresistance effect element 10 increases and hence a large DC voltage V_{DC} can be output from the output port p3. Further, the magnetoresistance effect device 120 according to the third embodiment can be used as the magnetic sensor or the rectifier.

Further, the magnetoresistance effect device 120 of the third embodiment can be used as the dielectric sensor similarly to the magnetoresistance effect device 100 of the first embodiment. FIG. 36 is a schematic diagram when the magnetoresistance effect device 120 is used as the dielectric sensor. The dielectric sensor using the magnetoresistance effect device 120 includes the installation area A1 or the installation area A2. In the magnetoresistance effect device 120, the object to be measured of the dielectric is installed in at least one of the installation area A1 and the installation area A2 and measurement is performed. The operation principle of the sensor is the same as that of the dielectric sensor of the first embodiment.

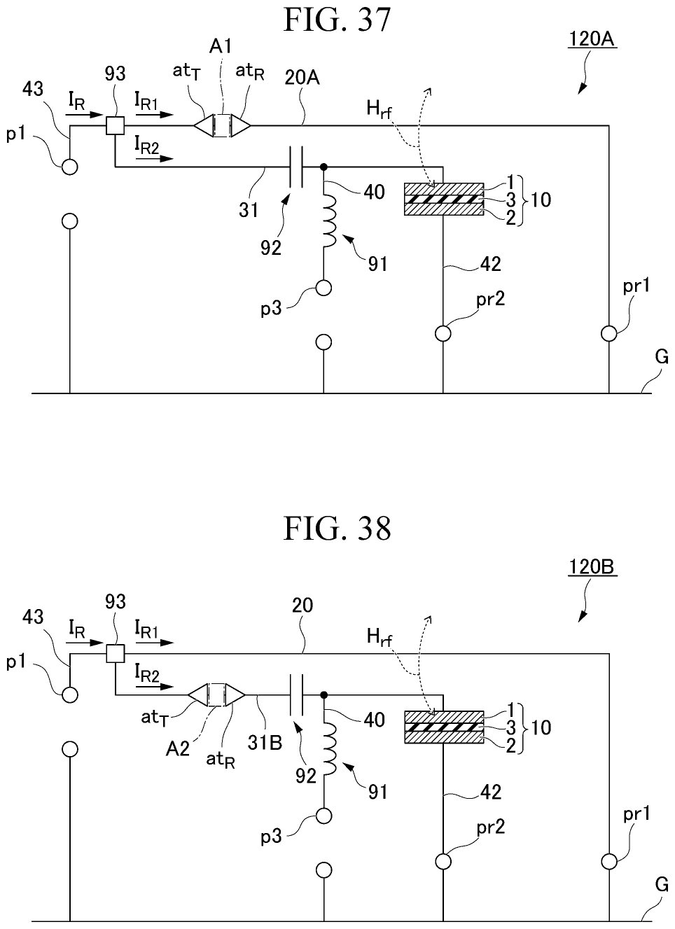

Further, FIGS. 37 and 38 are schematic diagrams of another example when the magnetoresistance effect device 120 is used as the dielectric sensor. In a magnetoresistance effect device 120A shown in FIG. 37, the first signal line 20A includes the transmission antenna at_{T} and the reception antenna at_{R} and the installation area A1 is an area sandwiched between the transmission antenna at_{T} and the reception antenna at_{R}. In a magnetoresistance effect device 120B shown in FIG. 38, a second signal line 31B includes the transmission antenna at_{T} and the reception antenna at_{R} and the installation area A2 is an area sandwiched between the transmission antenna at_{T} and the reception antenna at_{R}. In the magnetoresistance effect device 120A, the object to be measured of the dielectric is installed in the installation area A1 and measurement is performed. In the magnetoresistance effect device 120B, the object to be measured of the dielectric is installed in the installation area A2 and measurement is performed. The operation principle of the sensor is the same as that of the dielectric sensor of the first embodiment.

Although the third embodiment has been described with reference to the drawings, each configuration in the third embodiment and a combination thereof are examples and the configuration can be added, omitted, replaced, and modified in other forms without departing from the spirit of the present disclosure. For example, in the third embodiment, the magnetoresistance effect element 10 is one example. However, the plurality of magnetoresistance effect elements 10 may be connected to the second signal line 31 so that the second high frequency current IR₂ flows through the plurality of magnetoresistance effect elements 10 and the high frequency magnetic field H_{rf} caused by the first high frequency current IR₁ flowing through the first signal line 20 may be applied to the first ferromagnetic layers 1 of the plurality of magnetoresistance effect elements 10.

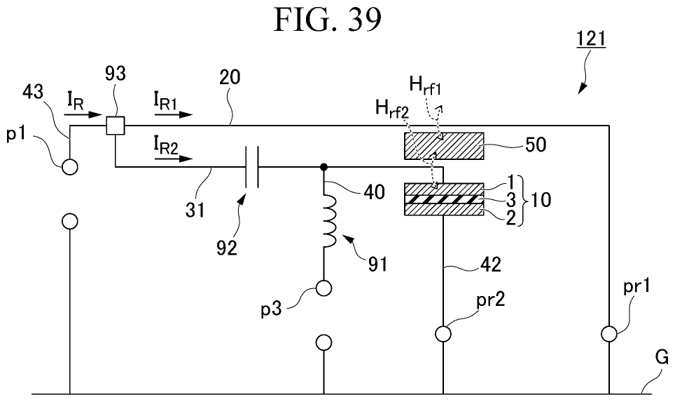

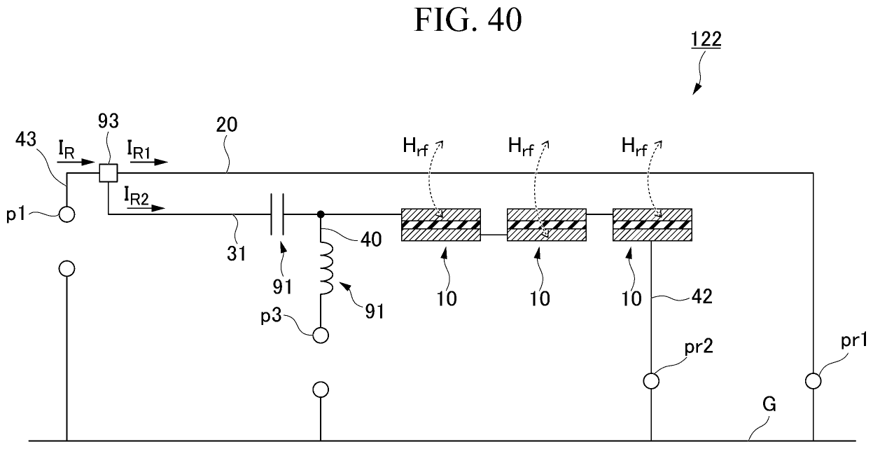

For example, also in the third embodiment, the same modifications and modified examples as those of the first embodiment can be applied and the modifications and modified examples can be combined with each other. For example, as in a magnetoresistance effect device 121 shown in FIG. 39, the magnetic material portion 50 may be provided and the high frequency magnetic field generated by the oscillation of the magnetization of the magnetic material portion 50 may be applied to the first ferromagnetic layer 1. Further, for example, as in a magnetoresistance effect device 122 shown in FIG. 40, the plurality of magnetoresistance effect elements 10 may be provided and the direction of the high frequency magnetic field H_{rf} applied to the first ferromagnetic layer 1 of each of the magnetoresistance effect elements 10 may be different in the plurality of magnetoresistance effect elements 10 similarly to the third modified example of the first embodiment. In the magnetoresistance effect device 122 shown in FIG. 40, each of the magnetoresistance effect elements 10 is connected to the second signal line 31 and the magnetoresistance effect elements 10 are connected in series to each other.

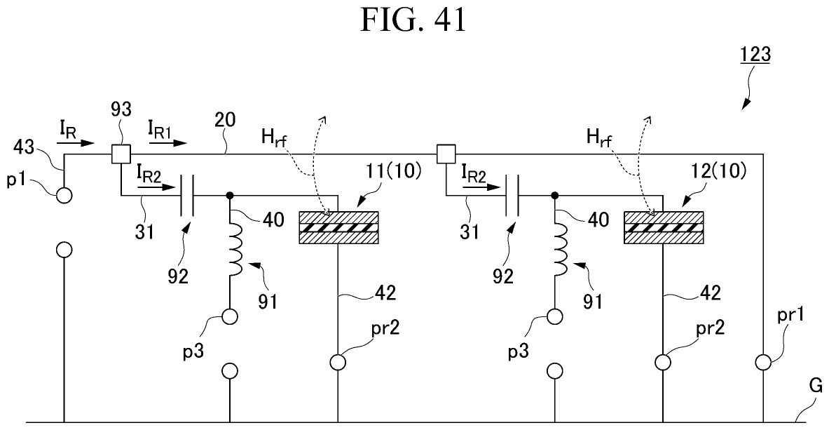

Further, for example, as in a magnetoresistance effect device 123 shown in FIG. 41, the plurality of magnetoresistance effect elements may be provided (the first magnetoresistance effect element 11 and the second magnetoresistance effect element 12 may be provided) and an angle formed between the first extension direction and the second extension direction may be 90° similarly to the fourth modified example of the first embodiment.

Further, in the first to third embodiments, the magnetic field application unit that applies the static magnetic field to the magnetoresistance effect element 10 may be provided positioned closer to the magnetoresistance effect element 10. The magnetic field application unit is configured as, for example, an electromagnet type or a stripline type magnetic field application mechanism capable of variably controlling the applied magnetic field strength by either voltage or current. Further, the magnetic field application unit may be configured as a combination of an electromagnet type or a stripline type magnetic field application mechanism capable of variably controlling the applied magnetic field strength and a permanent magnet that supplies only a constant magnetic field.

The magnetic sensors of the first embodiment, the second embodiment, and the third embodiment can be used, for example, as geomagnetic sensors, reading elements of magnetic heads of magnetic recording/reproducing devices such as hard disk drives, angle sensors for detecting an angular position of an object, and the like.

While preferred embodiments of the disclosure have been described and illustrated above, it should be understood that these are exemplary of the disclosure and are not to be considered as limiting. Additions, omissions, substitutions, and other modifications can be made without departing from the spirit or scope of the present disclosure. Accordingly, the invention is not to be considered as being limited by the foregoing description, and is only limited by the scope of the appended claims.

What is claimed is:

1. A magnetoresistance effect device comprising:
at least one magnetoresistance effect element;
at least one first signal line; and
an output port,
wherein the magnetoresistance effect element includes a first ferromagnetic layer, a second ferromagnetic layer, and a spacer layer sandwiched between the first ferromagnetic layer and the second ferromagnetic layer,
wherein the first signal line is separated from the magnetoresistance effect element with an insulator interposed therebetween and a high frequency magnetic field caused by a first high frequency current flowing through the first signal line is applied to the first ferromagnetic layer,
wherein a high frequency current flows through the magnetoresistance effect element, and
wherein a signal including a DC signal component caused by an output of the magnetoresistance effect element is output from the output port.

2. The magnetoresistance effect device according to claim 1, further comprising:
a first input port;
a second input port; and
a second signal line,
wherein the first input port is connected to the first signal line and a first high frequency signal generating the first high frequency current in the first signal line is input to the first input port,
wherein the first signal line is separated from the second signal line with an insulator interposed therebetween,
wherein the second input port is connected to the second signal line and a second high frequency signal generating a second high frequency current in the second signal line is input to the second input port, and
wherein the second signal line is connected to the magnetoresistance effect element and the second high frequency current flowing through the second signal line flows through the magnetoresistance effect element as the high frequency current.

3. The magnetoresistance effect device according to claim 1, further comprising:
a first input port,
wherein the first input port is connected to the first signal line and a first high frequency signal generating the first high frequency current in the first signal line is input to the first input port,
wherein the first signal line is connected to the magnetoresistance effect element, and
wherein the first high frequency current flowing through the first signal line flows through the magnetoresistance effect element as the high frequency current.

4. The magnetoresistance effect device according to claim 1, further comprising:
a first input port; and
a second signal line,
wherein the first input port is connected to the first signal line and the second signal line and a first high frequency signal generating the first high frequency current in the first signal line and generating a second high frequency current in the second signal line is input to the first input port, and
wherein the second signal line is connected to the magnetoresistance effect element and the second high frequency current flowing through the second signal line flows through the magnetoresistance effect element as the high frequency current.

5. The magnetoresistance effect device according to claim 1, further comprising:
a yoke which sandwiches the magnetoresistance effect element in a gap in a plan view in a lamination direction of the magnetoresistance effect element,
wherein the yoke is positioned closer to the second ferromagnetic layer than the first ferromagnetic layer, and
wherein the yoke applies a magnetic field generated in the gap by an external magnetic field to the second ferromagnetic layer.

6. The magnetoresistance effect device according to claim 1, further comprising:
a yoke which sandwiches the magnetoresistance effect element in a gap in a plan view in a lamination direction of the magnetoresistance effect element,
wherein the yoke is positioned closer to the first ferromagnetic layer than the second ferromagnetic layer, and
wherein the yoke applies a magnetic field generated in the gap by an external magnetic field to the first ferromagnetic layer.

7. The magnetoresistance effect device according to claim 1,
wherein the first signal line is positioned closer to the first ferromagnetic layer than the second ferromagnetic layer.

8. The magnetoresistance effect device according to claim 1, further comprising:
one or more magnetoresistance effect elements which are connected to the magnetoresistance effect element,
wherein directions of the high frequency magnetic field applied to the first ferromagnetic layer are different from each other in at least two magnetoresistance effect elements.

9. The magnetoresistance effect device according to claim 1
wherein the first signal line includes an extension portion which extends in a direction intersecting a lamination direction of the magnetoresistance effect element in a plan view in the lamination direction,
wherein the extension portion does not overlap the magnetoresistance effect element in the plan view in the lamination direction and partially overlaps the magnetoresistance effect element in a plan view in a direction perpendicular to the lamination direction, and
wherein the high frequency magnetic field caused by a high frequency current flowing through the extension portion is applied to the first ferromagnetic layer.

10. The magnetoresistance effect device according to claim 1,
wherein the at least one magnetoresistance effect element comprises a plurality of magnetoresistance effect elements,
wherein the at least one first signal line comprises one first signal line or a plurality of first signal lines, and
wherein an angle formed by a first extension direction in which the first signal line extends at a position overlapping a first magnetoresistance effect element of the magnetoresistance effect elements in a plan view in a lamination direction of the first magnetoresistance effect element and a second extension direction in which the first signal line extends at a position overlapping a second magnetoresistance effect element of the magnetoresistance effect elements in a plan view in a lamination direction of the second magnetoresistance effect element is 90°.

11. The magnetoresistance effect device according to claim 1,
wherein an in-plane component of an effective magnetic field in the first ferromagnetic layer is parallel or antiparallel to a oscillation direction of the high frequency magnetic field applied to the first ferromagnetic layer.

12. A sensor comprising:
the magnetoresistance effect device according to claim 1.
